(19) United States
(12) Patent Application Publication
(10) Pub. No.: US 2026/0051777 A1
(43) Pub. Date: Feb. 19, 2026

(54) FLEXIBLE CIRCUIT BOARD AND ROTATING ELECTRIC MACHINE

(71) Applicant: HONDA MOTOR CO., LTD., Tokyo (JP)

(72) Inventor: Daiki Suetsugu, Wako-shi (JP)

(21) Appl. No.: 19/289,817

(22) Filed: Aug. 4, 2025

(30) Foreign Application Priority Data
Aug. 13, 2024 (JP) 2024-135062
Aug. 13, 2024 (JP) 2024-135063

(51) Int. Cl. H02K 3/26; H05K 1/02; H05K 1/11

(52) U.S. Cl. CPC H02K 3/26; H05K 1/0277; H05K 1/115; H05K 2201/1009

(57) ABSTRACT

A flexible circuit board includes a first sub-circuit board and a second sub-circuit board. The first sub-circuit board has a connection portion arranged at a first longitudinal end, and has a connection setting between connection terminals and external terminals of a plurality of phases U, V, W set to a first connection setting that generates a rotating magnetic field in a direction. The second sub-circuit board has a connection portion arranged at a second longitudinal end, and has a connection setting between connection terminals and external terminals of U, V, W set to a second connection setting that generates a rotating magnetic field in a direction. The first sub-circuit board and the second sub-circuit board are bent into a cylindrical shape with the first longitudinal end and the second longitudinal end adjacent to each other to form a stator for a rotating electric machine.

### INCORPORATION BY REFERENCE

The present application claims priority under 35 U.S.C. § 119 to Japanese Patent Application No. 2024-135062 filed on Aug. 13, 2024 and Japanese Patent Application No. 2024-135063 filed on Aug. 13, 2024. The content of the applications is incorporated herein by reference in its entirety.

### BACKGROUND OF THE INVENTION

### Field of the Invention

The present invention relates to a flexible circuit board and a rotating electric machine.

### Description of the Related Art

Conventionally, a technique for configuring a stator of a motor with a flexible circuit board is known (see, for example, Japanese Patent Laid-Open No. 2006-067756). Japanese Patent Laid-Open No. 2006-067756 discloses a cylindrical brushless motor having: a stator in which a band-shaped flexible circuit board, on which a three-phase coil pattern is formed and input terminals are provided, is bent into a cylindrical shape; and a permanent magnet rotor arranged on the inner circumference of the stator.

Furthermore, a technique for configuring a stator of an electric motor with a flexible circuit board is known (see, for example, Japanese Patent Laid-Open No. 2024-021472 and Japanese Patent Laid-Open No. 11-297557). These patent literatures disclose a configuration in which a cover film is attached to the surface of a flexible board to increase the strength of the flexible board.

The flexible circuit board is manufactured by printing a circuit wire pattern with a printing device. Therefore, when a stator of a motor is configured with a band-shaped flexible circuit board, a long and large-area flexible circuit board is required to be compatible with to a large motor. However, producing such a long and large-area flexible circuit board disadvantageously requires introducing a printing device capable of printing large-sized flexible circuit boards. Furthermore, if a long flexible circuit board is configured by merely arraying a plurality of short flexible circuit boards of the same specifications, there is a disadvantage that the number of connection points with the external circuit is required for the number of short flexible circuits, which complicates routing of the wires to the external circuit.

Reducing the thickness of the flexible board makes it possible to reduce the size of electric motors and the like that are configured with the flexible board. In order to reduce the thickness of the flexible board, it is possible to consider eliminating attachment of a cover film and filling of resin for surface protection, but eliminating these has the disadvantage of decreasing the strength of the flexible board.

The present application has been made in view of such a background, and an object thereof is to provide a flexible circuit board that can eliminate the need for a long-length printing process and form a stator that is compatible with a large motor and is easily connected to an external circuit.

Another object of the present application is to provide a flexible board in which decrease in strength is prevented to reduce its thickness.

### SUMMARY OF THE INVENTION

A first aspect for achieving the above object is a flexible circuit board, including a first sub-circuit board and a second sub-circuit board each including a flexible, band-shaped insulating sheet, a predetermined number of coil wires for a plurality of phases, and a connection portion having the predetermined number of connection terminals individually connected to the predetermined number of the coil wires, the predetermined number of the coil wires being formed so as to extend in a longitudinal direction of the insulating sheet and being arranged in parallel at intervals, wherein the first sub-circuit board has the connection portion arranged at a first longitudinal end that is one longitudinal end of the insulating sheet, and has a connection setting set to a first connection setting, the connection setting being made between the predetermined number of the connection terminals and an external circuit to supply drive currents of the plurality of phases, the first connection setting being made in such a manner that a rotating magnetic field in a predetermined direction in a longitudinal direction of the insulating sheet is generated by the coil wires when drive currents of the plurality of phases are supplied from the external circuit to the predetermined number of the connection terminals, the second sub-circuit board has the connection portion arranged at a second longitudinal end that is another longitudinal end of the insulating sheet, and has a connection setting set to a second connection setting, the connection setting being made between the predetermined number of the connection terminals and the external circuit, the second connection setting being made in such a manner that a rotating magnetic field in the predetermined direction in a longitudinal direction of the insulating sheet is generated by the coil wires when drive currents of the plurality of phases are supplied from the external circuit to the predetermined number of the connection terminals, and the first sub-circuit board and the second sub-circuit board are arrayed in a longitudinal direction of the insulating sheet with the first longitudinal end of the first sub-circuit board and the second longitudinal end of the second sub-circuit board adjacent to each other, and are bent into a cylindrical shape, thereby forming a stator for a rotating electric machine.

The flexible circuit board may be configured such that the second sub-circuit board is configured in such a manner that a first surface and a second surface of the first sub-circuit board are inverted around an axis in a short-side direction of the insulating sheet.

The flexible circuit board may be configured such that the first sub-circuit board and the second sub-circuit board are arrayed in a longitudinal direction of the insulating sheet with the first longitudinal end of the first sub-circuit board and the second longitudinal end of the second sub-circuit board adjacent to each other to create a paired circuit board, and a plurality of sets of the paired circuit boards are arrayed in a longitudinal direction of the insulating sheet.

The flexible circuit board may be configured such that the first sub-circuit board and the second sub-circuit board each have a reinforcing wire formed in a space of the insulating sheet between ends of the coil wires in a short-side direction of the insulating sheet and the first longitudinal end or the second longitudinal end on at least one of first and second surfaces of the insulating sheet, the reinforcing wire being conductive to one of ends of the adjacent coil wires in a short-side direction of the insulating sheet, the reinforcing wire extending in a longitudinal direction of the insulating sheet toward another of ends of the adjacent coil wires.

The flexible circuit board may be configured such that the first sub-circuit board and the second sub-circuit board each have a positioning protrusion formed at an end of the insulating sheet in a short-side direction.

A second aspect for achieving the above object is a rotating electric machine, including: a first sub-circuit board and a second sub-circuit board each including a flexible, band-shaped insulating sheet, a predetermined number of coil wires for a plurality of phases, and a connection portion having the predetermined number of connection terminals individually connected to the predetermined number of the coil wires, the predetermined number of the coil wires being formed so as to extend in a longitudinal direction of the insulating sheet and being arranged in parallel at intervals, wherein the first sub-circuit board has the connection portion arranged at a first longitudinal end that is one longitudinal end of the insulating sheet, and has a connection setting set to a first connection setting, the connection setting being made between the predetermined number of the connection terminals and an external circuit to supply drive currents of the plurality of phases, the first connection setting being made in such a manner that a rotating magnetic field in a predetermined direction in a longitudinal direction of the insulating sheet is generated by the coil wires when drive currents of the plurality of phases are supplied from the external circuit to the predetermined number of the connection terminals, and the second sub-circuit board has the connection portion arranged at a second longitudinal end that is another longitudinal end of the insulating sheet, and has a connection setting set to a second connection setting, the connection setting being made between the predetermined number of the connection terminals and the external circuit, the second connection setting being made in such a manner that a rotating magnetic field in the predetermined direction in a longitudinal direction of the insulating sheet is generated by the coil wires when drive currents of the plurality of phases are supplied from the external circuit to the predetermined number of the connection terminals; and a stator configured in such a manner that the first sub-circuit board and the second sub-circuit board are arrayed in a longitudinal direction of the insulating sheet with the first longitudinal end of the first sub-circuit board and the second longitudinal end of the second sub-circuit board adjacent to each other, and are bent into a cylindrical shape.

A third aspect for achieving the above object is a flexible circuit board including: an insulating sheet having flexibility and a band shape; a plurality of first wires that are formed in parallel in a longitudinal direction of the insulating sheet and extend in a short-side direction of the insulating sheet, on a first surface of the insulating sheet; and a first reinforcing wire that is formed in a space on the first surface so as to be conductive to one of the first wires of the adjacent first wires and extend in a longitudinal direction of the insulating sheet toward another of the first wires of the adjacent first wires, the space being located between ends of a plurality of the first wires on at least one side in a short-side direction of the insulating sheet and a corresponding end of the insulating sheet in a short-side direction.

The flexible circuit board of the third aspect may be configured such that the first reinforcing wire includes a first first reinforcing wire that is conductive to one of the first wires of the adjacent first wires, and a second first reinforcing wire that is conductive to another of the first wires of the adjacent first wires, and the first first reinforcing wire and the second first reinforcing wire are formed with an interval in a short-side direction of the insulating sheet and are formed in such a manner as to have positions in a longitudinal direction of the insulating sheet partially overlapping each other.

The flexible circuit board of the third aspect may be configured to further include: a plurality of second wires that are formed in parallel in a longitudinal direction of the insulating sheet and extend in a short-side direction of the insulating sheet, on a second surface of the insulating sheet; and a second reinforcing wire that is formed in a space on the second surface so as to be conductive to one of the second wires of the adjacent second wires and extend in a longitudinal direction of the insulating sheet toward another of the second wires of the adjacent second wires, the space being located between ends of a plurality of the second wires on at least one side in a short-side direction of the insulating sheet and a corresponding end of the insulating sheet in a short-side direction.

The flexible circuit board of the third aspect may be configured such that the first reinforcing wire and the second reinforcing wire adjacent to each other in a longitudinal direction of the insulating sheet via the insulating sheet are formed in such a manner as to have positions in a longitudinal direction of the insulating sheet partially overlapping each other.

The flexible circuit board of the third aspect may be configured such that the second reinforcing wire includes a first second reinforcing wire that is conductive to one of the second wires of the adjacent second wires, and a second second reinforcing wire that is connected to another of the second wires of the adjacent second wires, and the first second reinforcing wire and the second second reinforcing wire are formed with an interval in a short-side direction of the insulating sheet and are formed in such a manner as to have positions in a longitudinal direction of the insulating sheet partially overlapping each other.

The flexible circuit board of the third aspect may be configured such that a plurality of the first wires and the second wires are arranged in parallel in such a manner as to have end positions overlapping each other in a normal direction of the insulating sheet at the same intervals, and opposing ends of a plurality of the first wires and the second wires via the insulating sheet are connected by vias to form a continuous wire that forms a coil.

A fourth aspect for achieving the above object is a rotating electric machine including a stator configured with a flexible circuit board, wherein the flexible circuit board includes: an insulating sheet having flexibility and a band shape; a plurality of first wires that are formed in parallel in a longitudinal direction of the insulating sheet and extend in a short-side direction of the insulating sheet, on a first surface of the insulating sheet; a first reinforcing wire that is formed in a space on the first surface so as to be conductive to one of the first wires of the adjacent first wires and extend in a longitudinal direction of the insulating sheet toward another of the first wires of the adjacent first wires, the space being located between ends of a plurality of the first wires on at least one side in a short-side direction of the insulating sheet and a corresponding end of the insulating sheet in a short-side direction; and a plurality of second wires that are formed in parallel in a longitudinal direction of the insulating sheet and extend in a short-side direction of the insulating sheet, on a second surface of the insulating sheet, and the flexible circuit board has a plurality of the first wires and the second wires that are arranged in parallel in such a manner as to have end positions overlapping each other in a normal direction of the insulating sheet at the same intervals, and opposing ends of a plurality of the first wires and the second wires via the insulating sheet are connected by vias to form a continuous wire that forms a coil.

The rotating electric machine of the fourth aspect may be configured such that the flexible circuit board includes a second reinforcing wire that is formed in a space on the second surface so as to be conductive to one of the second wires of the adjacent second wires and extend in a longitudinal direction of the insulating sheet toward another of the second wires of the adjacent second wires, the space being located between ends of a plurality of the second wires on at least one side in a short-side direction of the insulating sheet and a corresponding end of the insulating sheet in a short-side direction.

The flexible circuit board described above makes it possible to eliminate the need for a long-length printing process and form a stator that is compatible with a large motor and is easily connected to an external circuit.

The flexible circuit board of the third aspect described above makes it possible to prevent decrease in its strength while reducing its thickness. In addition, the electric motor of the fourth aspect is provided with a stator with the flexible circuit board, thereby making it possible to reduce its size and weight.

### BRIEF DESCRIPTION OF THE DRAWINGS

FIG. 1 is an explanatory diagram of a flexible circuit board configured with two sub-circuit boards;

FIG. 2 is an explanatory diagram of a motor including a stator configured with the flexible circuit board shown in FIG. 1;

FIG. 3 is an explanatory diagram of rotating magnetic fields generated in the stator configured with the flexible circuit board shown in FIG. 1;

FIG. 4 is an explanatory diagram of rotating magnetic fields generated in a stator configured with four sub-circuit boards;

FIG. 5 is an explanatory diagram of a first example of a flexible circuit board of another configuration with two sub-circuit boards;

FIG. 6 is an explanatory diagram of rotating magnetic fields generated in a stator configured with the flexible circuit board shown in FIG. 5;

FIG. 7 is an explanatory diagram of a second example of a flexible circuit board of another configuration with two sub-circuit boards;

FIG. 8 is an explanatory diagram of rotating magnetic fields generated in a stator configured with the flexible circuit board shown in FIG. 7;

FIG. 9 is an explanatory diagram of a first example of a configuration in which reinforcing wires are formed on a flexible circuit board;

FIG. 10 is an explanatory diagram of a second example of a configuration in which reinforcing wires are formed on a flexible circuit board;

FIG. 11 is an explanatory diagram of a third example of a configuration in which reinforcing wires are formed on a flexible circuit board;

FIG. 12 is an explanatory diagram of a configuration in which positioning protrusions are formed on a flexible circuit board;

FIG. 13 is an explanatory diagram showing a configuration of a flexible circuit board that forms a stator of an electric motor;

FIG. 14 is an explanatory diagram of an electric motor including a stator with a flexible circuit boards;

FIG. 15 is an explanatory diagram of a first embodiment of an arrangement mode of reinforcing wires;

FIG. 16 is an explanatory diagram of a second embodiment of an arrangement mode of reinforcing wires; and

FIG. 17 is an explanatory diagram of a third embodiment of an arrangement mode of reinforcing wires.

### DETAILED DESCRIPTION OF THE INVENTION

### 1. Configuration of Flexible Circuit Board and Motor

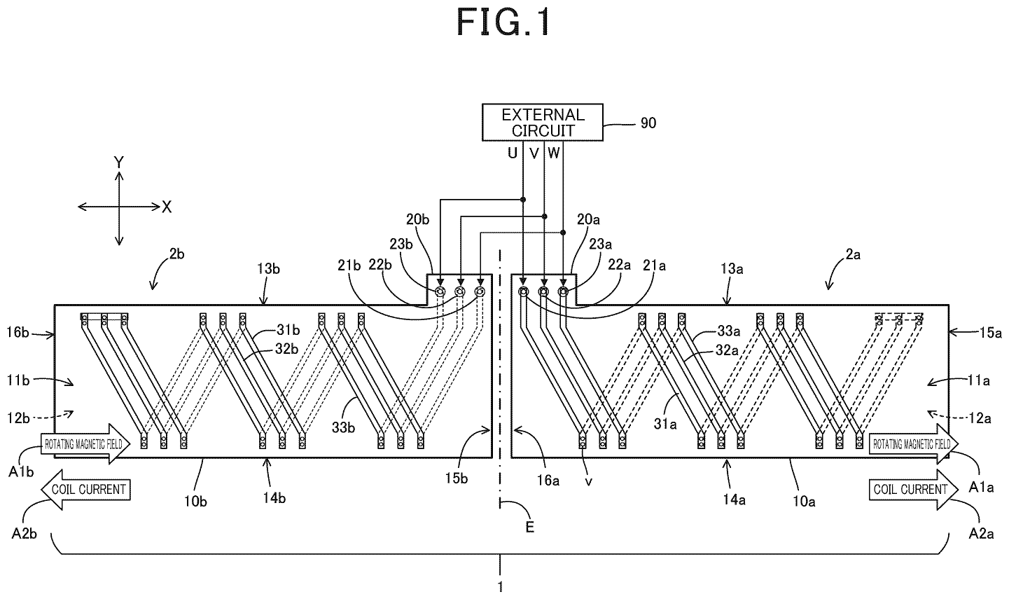

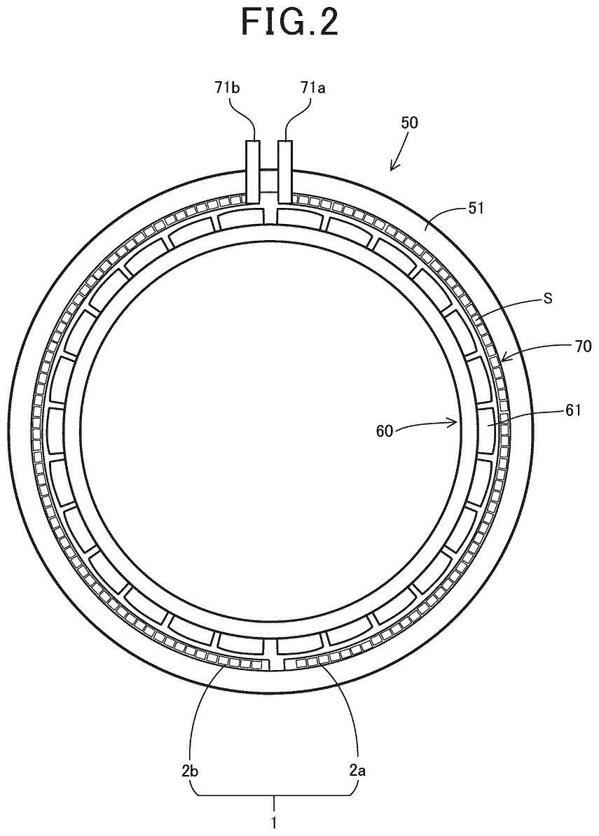

With reference to FIGS. 1 and 2, there is described configurations of a flexible circuit board 1 of this embodiment and a motor 50 (corresponding to a rotating electric machine of the present disclosure), which is a three-phase brushless motor configured with the flexible circuit board 1. Note that the rotating electric machine in which the flexible circuit board 1 is used may be a generator or the like in addition to a motor (electric motor). The configurations of the flexible circuit board 1 and the motor 50 are the same as those of a flexible circuit board and a motor described in Japanese Patent Laid-Open No. 2024-21472, and the flexible circuit board 1 and the motor 50 are manufactured through the same process. For ease of description, FIG. 1 shows a simplified circuit configuration of the flexible circuit board described in the above publication.

As shown in FIG. 2, the motor 50 is configured to include a stator 70 that has the flexible circuit board 1 bent into a cylindrical shape and is arranged outside a rotor 60 to which permanent magnets 61 are attached or embedded. Configuring the stator with the flexible circuit board 1 in this way makes it possible to reduce the weight of the stator compared to a configuration in which a coil is formed by winding a conductor wire as in a general stator. Note that there may be a configuration such that the stator 70 is arranged on the inner circumferential side of the rotor 60.

The flexible circuit board 1 makes it easy to increase the arrangement density of slots S of the stator 70. Increasing the arrangement density of the slots S makes it possible to shorten the magnetic path of the magnetic force generated in the electromagnetic coil of each slot S to make a metal portion 51 of the stator 70 thinner. This makes it possible to reduce the weight per volume of the motor 50.

With reference to FIG. 1, the flexible circuit board 1 is configured by arraying a first sub-circuit board 2a and a second sub-circuit board 2b in a longitudinal direction of the first sub-circuit board 2a and the second sub-circuit board 2b (a longitudinal direction of an insulating sheet 10a constituting the first sub-circuit board 2a and an insulating sheet 10b constituting the second sub-circuit board 2b). In the following, the description is made in which the longitudinal direction of the first sub-circuit board 2a and the second sub-circuit board 2b is an X direction. In addition, the description is made in which the short-side direction of the first sub-circuit board 2a and the second sub-circuit board 2b (the short-side direction of the insulating sheet 10a constituting the first sub-circuit board 2a and the insulating sheet 10b constituting the second sub-circuit board 2b) is a Y direction.

The first sub-circuit board 2a includes: a flexible, band-shaped insulating sheet 10a extending in the left-right direction in the figure; three coil wires 31a, 32a, 33a (the three is corresponding to a predetermined number of the present invention) formed by connecting a plurality of partial wires formed on each of the two opposing main surfaces (a first surface 11a, a second surface 12a) of the insulating sheet 10a through vias v at the Y-direction ends; and a connection portion 20a having connection terminals 21a, 22a, 23a to which the coil wires 31a, 32a, 33a are individually connected.

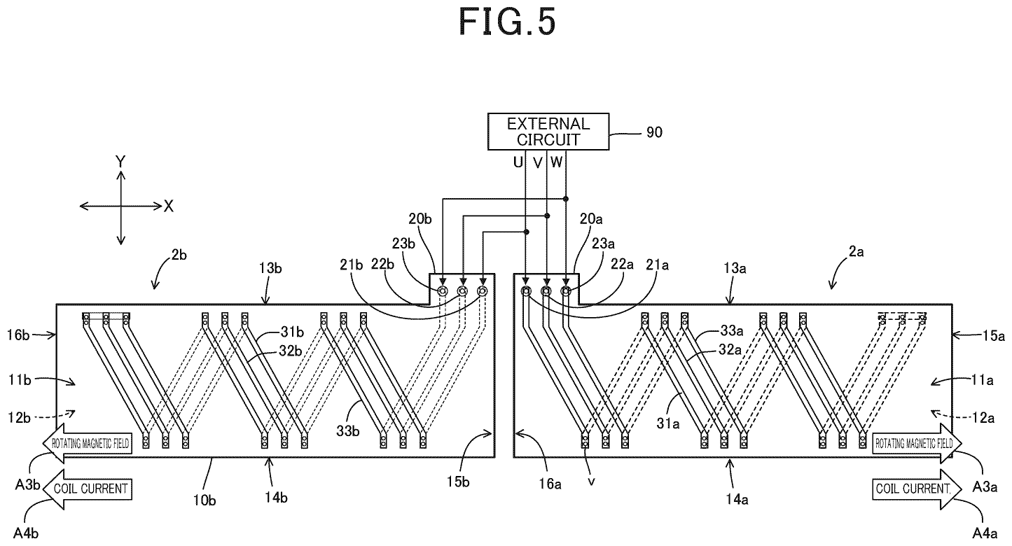

The three coil wires 31a, 32a, 33a cross each other in a chain shape without being conductive to each other. In FIG. 1, the wires (conductor pattern) formed on the first surface 11a (front surface) are shown by solid lines, and the wires formed on the second surface 12a (back surface) are shown by dashed lines. Similarly, in FIGS. 5, 7, 9, 10, 11, and 12 described below, the wires formed on the front surface in the figure are shown by solid lines, and the wires formed on the back surface are shown by dashed lines.

Of the two sides of the insulating sheet 10a extending in the X direction, the upper side in the figure is referred to as a long side 13a, and the lower side is referred to as a long side 14a. Of the two sides of the insulating sheet 10a extending in the Y direction, the side on the right side in the figure is referred to as a short side 15a, and the side on the left side is referred to as a short side 16a. In the first sub-circuit board 2a, the connection portion 20a is arranged at the end of the short side 16a side in the X direction (corresponding to a first longitudinal end in the present disclosure).

In the first sub-circuit board 2a, the connection setting between the connection portion 20a and the external circuit 90 that supplies drive currents of U, V, W phases is set as (connection terminal 21a, connection terminal 22a, connection terminal 23a)> (U phase, V phase, W phase) (corresponding to a first connection setting of the present disclosure). This makes coil currents flow from the left to the right in the figure as shown in A2a to generate a rotating magnetic field moving from the left to the right in the figure as shown in A1a. Ala corresponds to a predetermined direction in the present disclosure.

The second sub-circuit board 2b is formed by inverting the first sub-circuit board 2a around an axis E in the Y direction so that the first surface 11a and the second surface 12a are inverted. The second sub-circuit board 2b, like the first sub-circuit board 2a, includes an insulating sheet 10b, coil wires 31b, 32b, 33b formed on the insulating sheet 10b, and a connection portion 20b.

For the second sub-circuit board 2b, of the two sides of insulating sheet 10b extending in the X direction, the upper side in the figure is referred to as a long side 13b, and the lower side is referred to as a long side 14b. Of the two sides of the insulating sheet 10b extending in the Y direction, the side on the right side in the figure is referred to as a short side 15b, and the side on the left side is referred to as a short side 16b.

In the second sub-circuit board 2b, the connection portion 20b is arranged at the end of the short side 16b side in the X direction (corresponding to a second longitudinal end in the present disclosure). The connection setting between the connection portion 20b and the external circuit 90 that supplies drive currents of U, V, W phases is set as (connection terminal 23b, connection terminal 22b, connection terminal 21b)> (U phase, V phase, W phase) (corresponding to a second connection setting of the present invention). This makes coil currents flow from the right (short side 15b side) to the left (short side 16b side) in the figure as shown in A2b to generate a rotating magnetic field moving from the left to the right in the figure as shown in A1b.

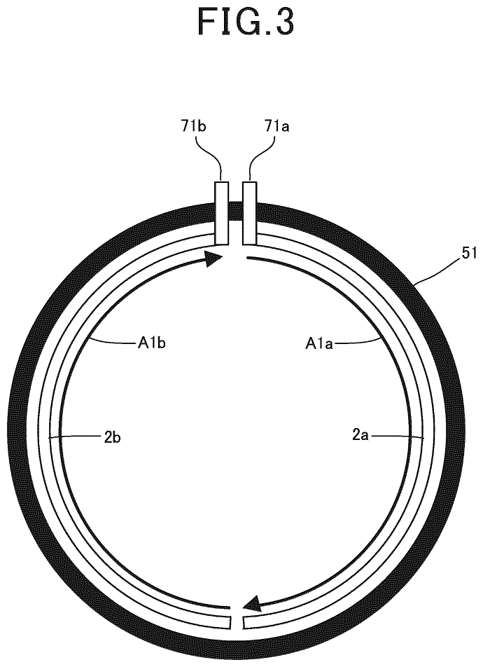

In other words, the direction of the rotating magnetic field generated in the first sub-circuit board 2a is the same as the direction of the rotating magnetic field generated in the second sub-circuit board 2b. FIG. 3 shows the directions of the rotating magnetic fields in a motor having a stator configured with the flexible circuit board 1 shown in FIG. 1. In FIG. 3, the first sub-circuit board 2a is arranged on the right, and the second sub-circuit board 2b is arranged on the left. In FIG. 3, a rotating magnetic field in the direction of A1a (clockwise) is generated by a three-phase (U, V, W) drive current supplied from a first external terminal 71a to the first sub-circuit board 2a. In addition, a rotating magnetic field in the direction of Alb, which is the same direction as Ala, is generated by the three-phase drive current supplied from a second external terminal 71b to the second sub-circuit board 2b. As a result, the rotor can be rotated normally.

Furthermore, the connection portion 20a of the first sub-circuit board 2a and the connection portion 20b of the second sub-circuit board 2b are adjacent to each other. This makes it possible to arrange the first external terminal 71a connected to the connection portion 20a and the second external terminal 71b connected to the connection portion 20b adjacently to each other. As a result, the motor 50 and external circuit 90 can be connected at a single point, making it easier to route the wires.

FIGS. 1 to 3 show an example of configuring a stator using one first sub-circuit board 2a and one second sub-circuit board 2b. However, it is possible to array the first sub-circuit board 2a and the second sub-circuit board 2b in the X direction to create a flexible circuit board 1 (corresponding to a paired circuit board of the present disclosure) as shown in FIG. 1, and array a plurality of sets of the flexible circuit boards 1, thereby easily configuring a long flexible circuit board capable of forming a stator compatible with a large motor.

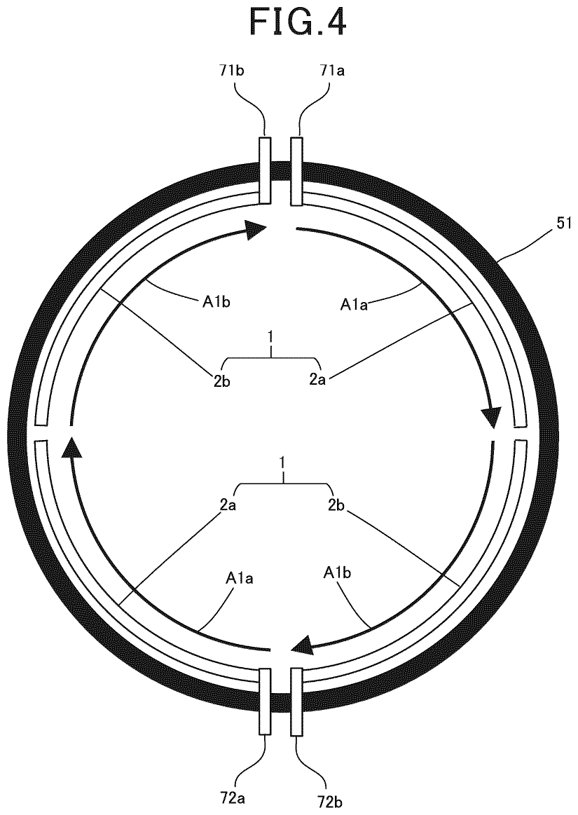

For example, FIG. 4 illustrates a motor in which two sets of flexible circuit boards 1 shown in FIG. 1 are arranged to configure a stator. In the configuration of FIG. 4, the directions (Ala, Alb) of the rotating magnetic field generated in the first sub-circuit board 2a and the second sub-circuit board 2b that form the flexible circuit board 1 on the upper side of FIG. 4 are the same as the directions (Ala, Alb) of the rotating magnetic field generated in the first sub-circuit board 2a and the second sub-circuit board 2b that form the flexible circuit board 1 on the lower side of FIG. 4. As a result, the rotor can be rotated normally.

### 2. Other Configuration Examples Using Two Sub-Circuit Boards

Cases in which a flexible circuit board is configured with a configuration other than that shown in FIG. 1 are described with reference to FIGS. 5 to 8.

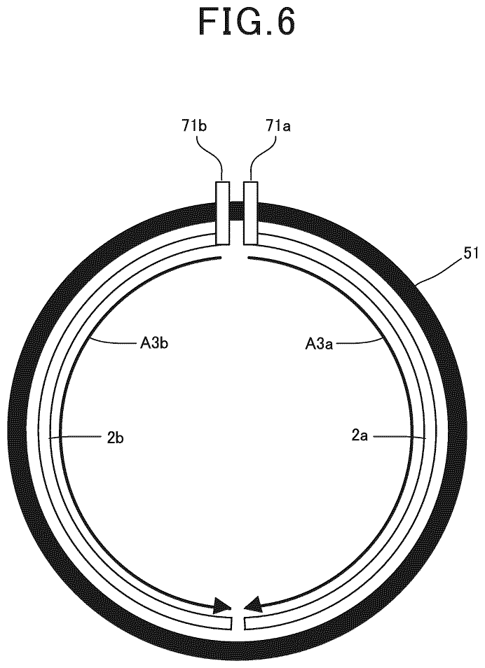

FIGS. 5 and 6 show a configuration in which the connection setting of the connection portion 20b of the second sub-circuit board 2b is not changed from that of the first sub-circuit board 2a, as shown in FIG. 5, in comparison with the configuration shown in FIG. 1. In other words, the connection setting is set as (connection terminal 23b, connection terminal 22b, connection terminal 21b)=(W phase, V phase, U phase). In this configuration, as shown in FIG. 5, the direction of the coil current (A4a and A4b) and the direction of the rotating magnetic field (A3a and A3b) of the first sub-circuit board 2a and the second sub-circuit board 2b are opposite to each other.

Therefore, when the stator is configured as shown in FIG. 6, the direction A3a of the rotating magnetic field generated by the first sub-circuit board 2a collides with the direction A3b of the rotating magnetic field generated by the second sub-circuit board 2b, making it impossible to rotate the rotor.

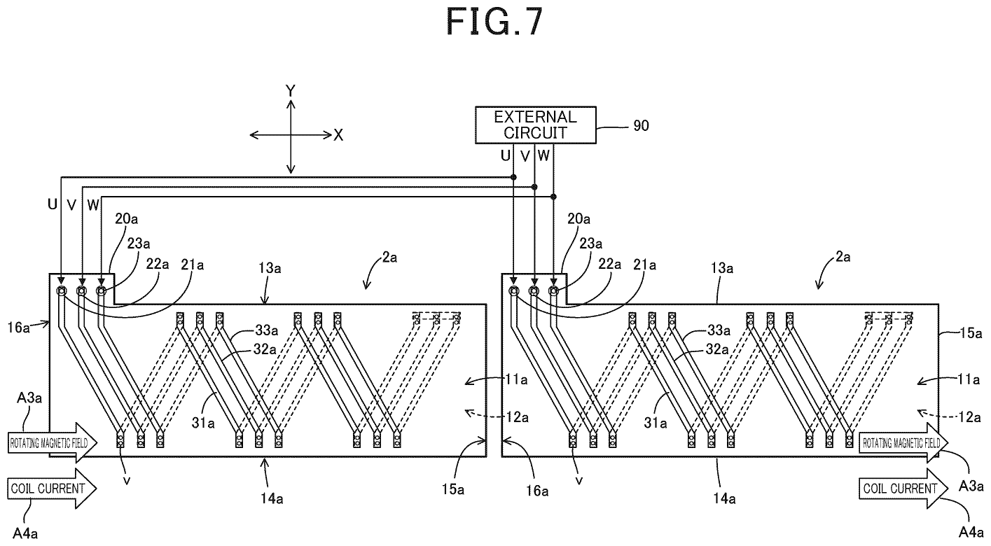

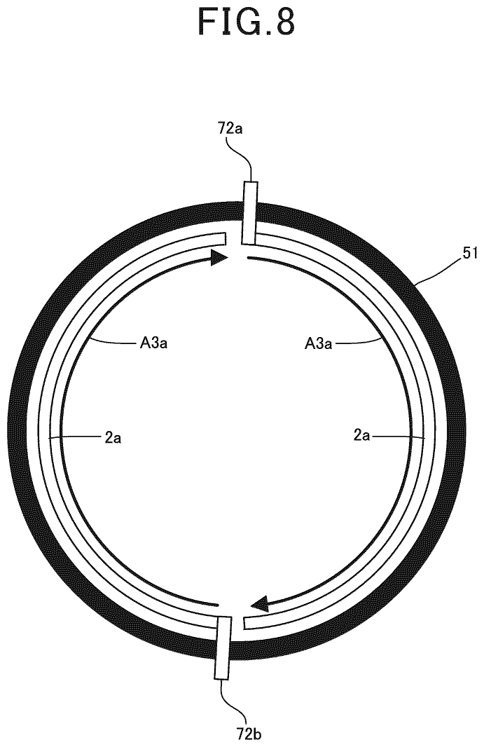

Furthermore, as shown in FIG. 7, FIGS. 7 and 8 show a configuration in which two first sub-circuit boards 2a are arranged side by side without being inverted. In this configuration, as shown in FIG. 7, the two first sub-circuit boards 2a have a direction of the coil current (A3a) that is the same as the direction of the generated rotating magnetic field (A3a).

As a result, when a stator is configured as shown in FIG. 8, the directions of the rotating magnetic fields generated by the two first sub-circuit boards 2a are both A3a, and the rotor can be rotated normally. However, the connection portions 20a of the two first sub-circuit boards 2a are both on the short side 16a sides. This causes the positions of the first external terminals 72a, 72b each connected to a corresponding one of the connection portions 20a of the two first sub-circuit boards 2a to separate from each other, as shown in FIG. 8. Therefore, compared to the configuration shown in FIGS. 1 and 2, there is a disadvantage that it is difficult to route the wires between the connection portions 20a, 20b and the external circuit 90.

### 3. Formation of Reinforcing Wires

In the first sub-circuit board 2a and the second sub-circuit board 2b of the flexible circuit board 1 shown in FIG. 1, reinforcing wires may be formed to increase the strength of the board. Providing reinforcing wires and eliminating need to attach a reinforcing sheet or fill resin makes it possible to reduce the thickness of the flexible circuit board 1. Furthermore, employing a stator configured with a flexible circuit board 1 with a reduced thickness in this manner makes it possible to reduce the size and weight of a rotating electric machine such as a motor. A configuration for forming reinforcing wires on the first sub-circuit board 2a is described below, and the same applies to the second sub-circuit board 2b.

### (First Example of Reinforcing Wires)

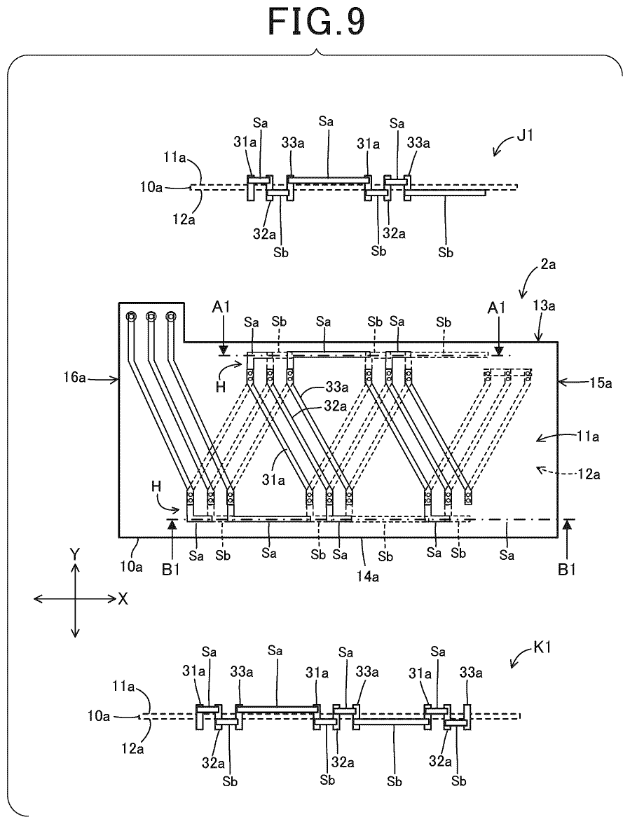

FIG. 9 shows a first example of a configuration for forming reinforcing wires. In the first example, for the first sub-circuit board 2a shown in FIG. 1, first reinforcing wires Sa are formed on the first surface 11a (front surface), and second reinforcing wires Sb are formed on the second surface 12a (back surface).

On the first surface 11a (front surface) of the insulating sheet 10a, on each of the long side 13a side and the long side 14a side, in the space H between the ends of the coil wires 31a, 32a, 33a and the Y-direction end of the insulating sheet 10a, L-shaped first reinforcing wires Sa are formed, each of which is conductive to the end of one of adjacent coil wires among coil wires 31a, 32a, 33a and extends in the X-direction toward the end of the other of the adjacent coil wires. For example, a first reinforcing wire Sa is formed on each end of the coil wire 31a in the Y direction, and extends in the X direction toward the adjacent coil wire 32a.

In the same way, on the second surface 12a (back surface) of the insulating sheet 10a, on each of the long side 13a side and the long side 14a side, in the space H between the ends of the coil wires 31a, 32a, 33a and the Y-direction end of the insulating sheet 10a, L-shaped second reinforcing wires Sb are formed, each of which is conductive to the end of one of adjacent coil wires among coil wires 31a, 32a, 33a and extends in the X-direction toward the end of the other of the adjacent coil wires. For example, a second reinforcing wire Sb is formed on each end of the coil wire 32a in the Y direction, and extends in the X direction toward the adjacent coil wire 33a.

J1 in FIG. 9 is a cross-sectional view taken along A1-A1 arrows of the first sub-circuit board 2a, with the insulating sheet 10a made transparent when viewed from the long side 13a. K1 is a cross-sectional view taken along B1-B1 arrows of the first sub-circuit board 2a, with the insulating sheet 10a made transparent when viewed from the long side 14a. As shown in K1 and J1, the first reinforcing wires Sa formed on the first surface 11a and the second reinforcing wires Sb formed on the second surface 12a have positions in the X direction partially overlapping each other.

As a result, wires are formed over the entire range in the X direction in which the coil pattern is formed on each side of the long side 13a and the long side 14b of the first sub-circuit board 2a, making it possible to increase the strength of the first sub-circuit board 2a. The first reinforcing wires Sa and the second reinforcing wires Sb may be formed on only one of the long sides 13a and 14a.

### (Second Example of Reinforcing Wires)

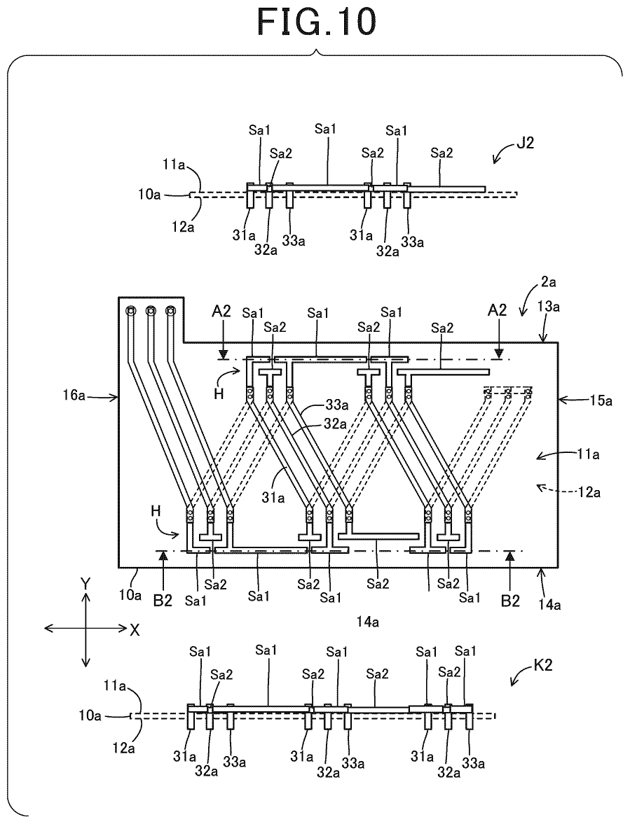

FIG. 10 shows a second example of a configuration for forming reinforcing wires. In the second example, the first first reinforcing wires Sa1 and the second first reinforcing wires Sa2 are formed on the first surface 11a (front surface) of the first sub-circuit board 2a shown in the first example.

On the first surface 11a (front surface) of the insulating sheet 10a, on each of the long side 13a side and the long side 14a side, in the space H between the ends of the coil wires 31a, 32a, 33a and the Y-direction end of the insulating sheet 10a, T shaped or L-shaped first first reinforcing wires Sa1 and second first reinforcing wires Sa2 are formed, each of which is conductive to the end of one of adjacent coil wires among coil wires 31a, 32a, 33a and extends in the X-direction toward the end of the other of the adjacent coil wires. The first first reinforcing wires Sa1 and the second first reinforcing wires Sa2 are arranged at a distance in the Y direction.

For example, the coil wires 31a each have an end on the long side 13a side and an end on the long side 14a side. One of the two ends has a first reinforcing wire Sa1 and the other of the two ends has a second reinforcing wire Sa2, each of which is conductive to the coil wire 31a and extend in the X direction toward the adjacent coil wires 32a, 33a.

J2 in FIG. 10 is a cross-sectional view taken along A2-A2 arrows of the first sub-circuit board 2a, with the insulating sheet 10a made transparent when viewed from the long side 13a. K2 is a cross-sectional view taken along B2-B2 arrows of the first sub-circuit board 2a, with the insulating sheet 10a made transparent when viewed from the long side 14a. As shown in J2 and K2, the first first reinforcing wires Sa1 and the second first reinforcing wires Sa2 formed on the first surface 11a are arranged to have positions in the X direction partially overlapping each other.

As a result, wires are formed over the entire range in the X direction in which the coil pattern is formed on each side of the long side 13a and the long side 14b of the first sub-circuit board 2a, making it possible to increase the strength of the first sub-circuit board 2a. The first first reinforcing wires Sa1 and the second first reinforcing wires Sa2 may be formed only on either the long side 13a side and the long side 14a side of the first sub-circuit board 2a.

### (Third Example of Reinforcing Wires)

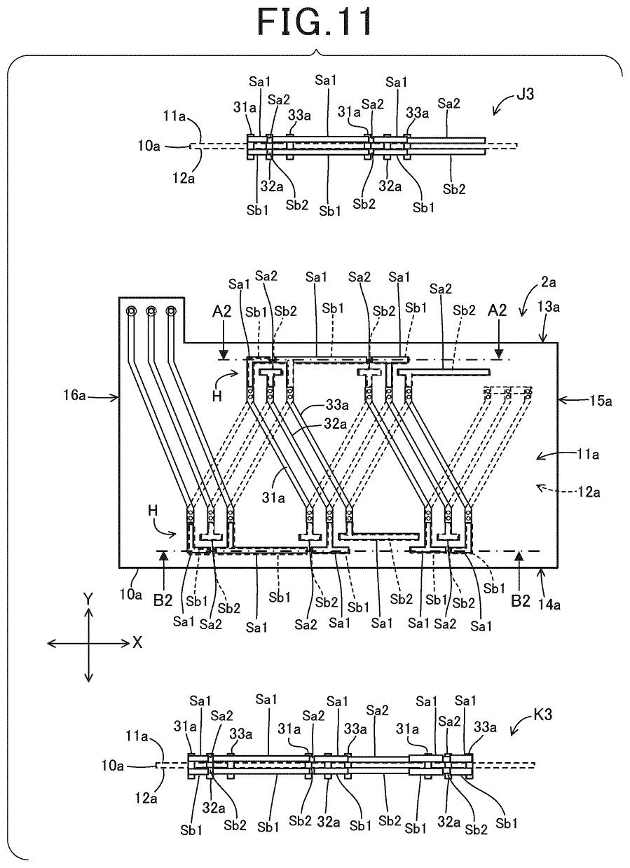

FIG. 11 shows a third example of a configuration for forming reinforcing wires. In the third example, for the first sub-circuit board 2a shown in FIG. 1, first first reinforcing wires Sa1 and second first reinforcing wires Sa2 are formed on the first surface 11a (front surface), and first second reinforcing wires Sb1 and second second reinforcing wires Sb2 are formed on the second surface 12a (back surface).

On the first surface 11a (front surface) of the insulating sheet 10a, the first first reinforcing wires Sa1 and the second first reinforcing wires Sa2 are formed in the same arrangement pattern as in the second example shown in FIG. 10. Also, on the second surface 12a (back surface) of the insulating sheet 10a, the first second reinforcing wires Sb1 and the second second reinforcing wires Sb2 are formed in the same arrangement pattern as in the second example shown in FIG. 10.

In other words, on both the first surface 11a (front surface) and the second surface 12a (back surface) of the insulating sheet 10a, the first first reinforcing wires Sa1 and the second first reinforcing wires Sa2 are formed for the first surface 11a (front surface), and the first second reinforcing wires Sb1 and the second second reinforcing wires Sb2 are formed for the second surface 12a (back surface) in the same arrangement pattern as the first first reinforcing wires Sa1 and the second first reinforcing wires Sa2 shown in the second example above.

J3 in FIG. 11 is a cross-sectional view of the first sub-circuit board 2a taken along A2-A2 arrows, viewed from the long side 13a, with the insulating sheet 10a made transparent. K3 is a cross-sectional view of the first sub-circuit board 2a taken along B2-B2 arrows, viewed from the long side 14a, with the insulating sheet 10a made transparent. As shown in J3 and K3, on the first surface 11a, the first first reinforcing wires Sa1 and the second first reinforcing wires Sa2 are formed to have positions in the X-direction partially overlapping each other, and on the second surface 12a, the first second reinforcing wires Sb1 and the second second reinforcing wires Sb2 are formed to have positions in the X-direction partially overlapping each other.

As a result, wires are formed on each of the first surface 11a (front surface) and the second surface 12a (back surface) of the first sub-circuit board 2a over the entire range in the X direction in which the coil pattern of the first sub-circuit board 2a is formed, on both the long side 13a side and long side 14a side of the first sub-circuit board 2a, making it possible to increase the strength of the first sub-circuit board 2a. Note that the first first reinforcing wires Sa1, the second first reinforcing wires Sa2, the first second reinforcing wires Sb1, and the second second reinforcing wires Sb2 may be formed on only one of the long side 13a side and long side 14a side.

### 4. Formation of Protrusions

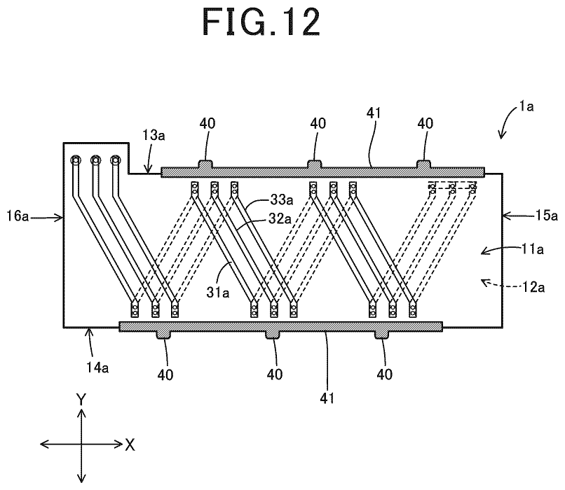

As shown in FIG. 12, the first sub-circuit board 2a and the second sub-circuit board 2b of the flexible circuit board 1 shown in FIG. 1 may be provided with a positioning protrusions 40 for arranging the first sub-circuit board 2a and the second sub-circuit board 2b in a predetermined position of the case 51 (see FIG. 2). In FIG. 12, an example is shown in which protrusions are provided on both the long side 13a side and the long side 14 side of the first sub-circuit board 2a, but protrusions 40 may be provided on only one of the long side 13a side and the long side 14a side.

If thermal conductive patterns 41 are formed on the protrusions 40 using a material with a higher thermal conductivity than the material of the insulating sheet 10a, the heat generated in the flexible circuit board 1 can be efficiently dissipated to the outside of the case 51 via the thermal conductive patterns 41 of the protrusions 40. The thermal conductive patterns 41 are made of the same metal (copper, etc.) as the coil wires 31a, 32a, 33a, etc.

### 5. Other embodiments

In the above embodiment, as shown in FIG. 1, the connection setting between the connection terminals 21b, 22b, 23b of the connection portion 20b of the second sub-circuit board 2b and the external terminals of the three phases U, V, W is (connection terminal 23b, connection terminal 22b, connection terminal 21b)> (U phase, V phase, W phase). However, the connection setting may be (connection terminal 23b, connection terminal 22b, connection terminal 21b)> (W phase, U phase, V phase) or (connection terminal 23b, connection terminal 22b, connection terminal 21b)> (V phase, W phase, U phase). These connection settings can cause the direction of the magnetic field generated in the second sub-circuit board 2b to be the same as the direction of the magnetic field generated in the first sub-circuit board 2a.

In the above embodiment, the second sub-circuit board 2b is configured by inverting the first surface 11a and the second surface 12a of the first sub-circuit board 2a. As another embodiment, for example, when it is necessary to match the specifications of the surface treatment of the first surfaces 11a, 11b or the second surfaces 12a, 12b of the first sub-circuit board 2a and the second sub-circuit board 2b, the first sub-circuit board 2a and the second sub-circuit board 2b may be prepared exclusively for them.

### 6. Further Other Embodiments

### [1. Configuration of Flexible Circuit Board and Motor]

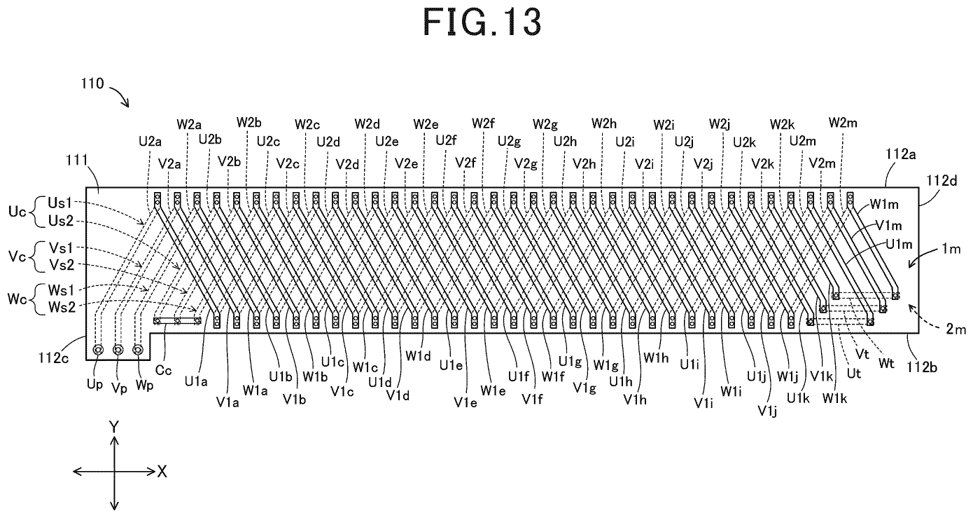

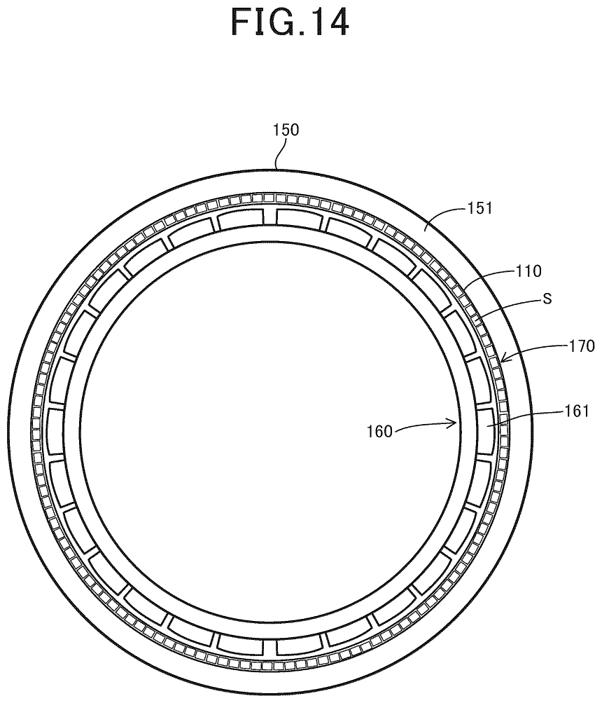

With reference to FIGS. 13 and 14, there is described basic configurations of a flexible circuit board 110 of this embodiment and a motor 150 (corresponding to a rotating electric machine of the present disclosure), which is a three-phase brushless motor configured with the flexible circuit board 110. Note that the rotating electric machine in which the flexible circuit board 110 is used may be a generator or the like in addition to a motor (electric motor). The configurations of the flexible circuit board 110 and the motor 150 are the same as those of a flexible circuit board and a motor described in Japanese Patent Laid-Open No. 2024-21472, and the flexible circuit board 110 and the motor 150 are manufactured through the same process.

As shown in FIG. 14, the motor 150 is configured to include a stator 170 that has the flexible circuit board 110 bent into a cylindrical shape and is arranged outside a rotor 160 to which permanent magnets 161 are attached or embedded. Configuring the stator with the flexible circuit board 110 in this way makes it possible to reduce the weight of the stator compared to a configuration in which a coil is formed by winding a conductor wire as in a general stator. Note that there may be a configuration such that the stator 170 is arranged on the inner circumferential side of the rotor 160.

The flexible circuit board 110 makes it easy to increase the arrangement density of slots S of the stator 170. Increasing the arrangement density of the slots S makes it possible to shorten the magnetic path of the magnetic force generated in the electromagnetic coil of each slot S to make a metal portion 151 of the stator 170 thinner. This makes it possible to reduce the weight per volume of the motor 150.

With reference to FIG. 13, the flexible circuit board 110 has a band-shaped insulating sheet 111 having flexibility and extending left and right in the figure, and a conductor pattern of a plurality of partial wires formed on each of the two opposing main surfaces (first surface 1 and second surface 2) of the insulating sheet 111. The partial wires formed on the two main surfaces are alternately connected in cascade through vias to form three independent continuous wires Uc, Vc, Wc. Three continuous wires Uc, Vc, Wc are energized with currents of U phase, V phase, and W phase of three phase AC respectively from external terminals Up, Vp, Wp. In the following description, the longitudinal direction of the insulating sheet 111 is defined as the X direction, and the short-side direction of the insulating sheet 111 is defined as the Y direction.

The three continuous wires Uc, Vc, Wc include first continuous portions Us1, Vs1, Ws1 and second continuous portions Us2, Vs2, Ws2, respectively, extending in the X-direction of the insulating sheet 111. In the continuous wires Uc, Vc, Wc, the first continuous portions Us1, Vs1, Ws1 and the second continuous portions Us2, Vs2, Ws2 cross each other, respectively, in a chain shape without being conductive to each other in a projected plan view (for example, the plan view shown in FIG. 13) seen from the normal direction of the main surface of the insulating sheet 111. In the continuous wires Uc, Vc, Wc, the first continuous portions Us1, Vs1, Ws1 respectively cross the second continuous portions Us2, Vs2, Ws in a chain shape, thereby forming a plurality of annular portions continuously arrayed in a chain shape. Each of these annular portions forms a single coil.

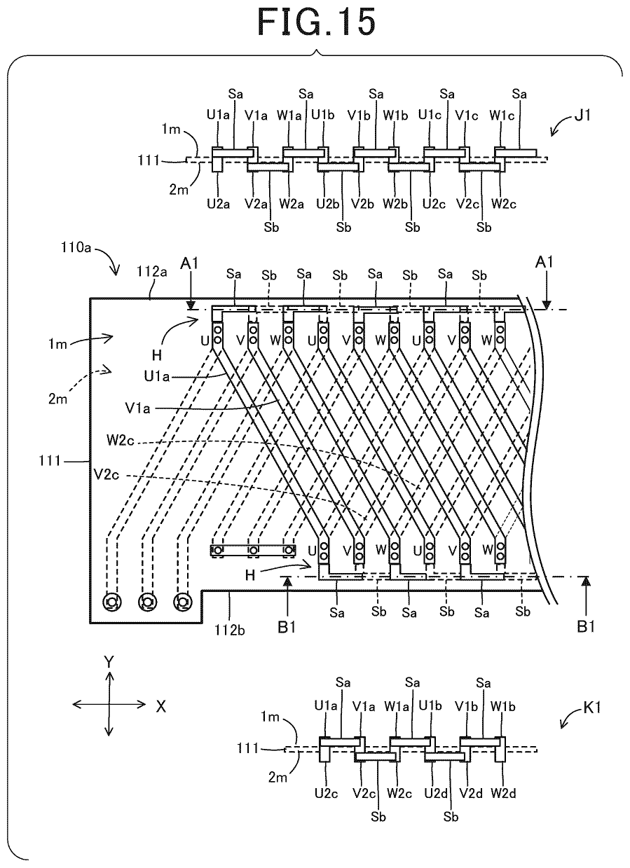

In FIG. 13, the conductor pattern formed on the first surface 1m (front surface) is shown by solid lines, and the conductor pattern formed on the second surface 2m (back surface) is shown by dashed lines. The same applies to each configuration of the flexible circuit board described in FIGS. 15 to 17 described below. Of the two sides of the insulating sheet 111 extending in the X direction, the side on the upper side in the figure is referred to as a long side 112a, and the side on the lower side in the figure is referred to as a long side 112b. Of the two sides of the insulating sheet 111 extending in the Y direction, the side on the left side in the figure is referred to as a short side 112c, and the side on the right side in the figure is referred to as a short side 112d.

In the motor 150, the flexible circuit board 110 is bent into a cylindrical shape so that the short side 112c and the short side 112d face each other, and is placed in a case 151. The inner surface side of the cylinder in this bent state may be either the first surface 1 or the second surface 2 of the insulating sheet 111.

With reference to FIG. 13, the configuration of three continuous wires Uc, Vc, Wc that are formed on the flexible circuit board 110 and are respectively energized with currents of U, V, W phases is described. The continuous wire Uc to be energized with the U phase current includes a first continuous portion Us1 and a second continuous portion Us2 extending in the X direction of the insulating sheet 111. The first continuous portion Us1 is configured by alternately cascading, through vias, corresponding ends of the second partial wires U2a, U2c, U2e, U2g, U2i, U2k formed on the second surface 2m (back surface) of the insulating sheet 111 and the first partial wires U1a, U1c, U1e, U1g, U1i, U1k formed on the first surface 1m (front surface) thereof.

The second continuous portion Us2 is configured by alternately cascading, through vias, the corresponding ends of the second partial wires U2b, U2d, U2f, U2h, U2j, U2a formed on the second surface 2m (back surface) and the first partial wires U1b, U1d, U1f, U1h, U1j, U1a formed on the first surface 1m (front surface).

Hereinafter, the first partial wires U1a, U1b, U1c, U1d, U1e, U1f, U1g, U1h, U1i, U1j, U1k, U1a are collectively referred to as the first partial wire U1. The second partial wires U2a, U2b, U2c, U2d, U2e, U2f, U2g, U2h, U2i, U2j, U2k, U2a are collectively referred to as the second partial wire U2.

One end of the first continuous portion Us1 (the end on the left side in FIG. 13) is connected to an external terminal Up to which a U phase current is input. The other end of the first continuous portion Us1 (the end on the right side in FIG. 13) and one end of the second continuous portion Us2 (the end on the right side in FIG. 13) are cascaded through the conductor pattern forming the inversion portion Ut, and are conductive to each other. The other end of the second continuous portion (the end on the left side in FIG. 13) is connected to the conductor pattern forming the common connection portion Cc. To the common connection portion Cc, the ends of continuous wires Vc, Wc to be energized with V phase and W phase currents described below are also connected (see FIG. 13).

Connecting in this manner forms a continuous wire Uc that conducts from the external terminal Up→first continuous portion Us1→inversion portion Ut→second continuous portion Us2→common connection portion Cc. Furthermore, the first continuous portion Us1 and the second continuous portion Us2 cross in a chain shape without mutual conduction in a projected plan view seen from the normal direction of the main surface of the insulating sheet 111. The annular portions continuously arrayed in a chain shape formed by the crossings each form a single coil.

The other two continuous wires Vc, Wc, which are respectively connected to external terminals Vp, Wp and are energized with V phase and W phase currents, are configured in the same manner as the above-described U phase continuous wire Uc.

Specifically, the continuous wire Vc to be energized with the V phase current includes a first continuous portion Vs1 and a second continuous portion Vs2 extending in the X direction of the insulating sheet 111. The first continuous portion Vs1 is configured by alternately cascading, through vias, corresponding ends of the second partial wires V2a, V2c, V2e, V2g, V2i, V2k formed on the second surface 2m (back surface) of the insulating sheet 111 and the first partial wires V1a, V1c, V1e, V1g, V1i, V1k formed on the first surface 1m (front surface) thereof.

The second continuous portion Vs2 is configured by alternately cascading, through vias, the corresponding ends of the second partial wires V2b, V2d, V2f, V2h, V2j, V2a formed on the second surface 2m (back surface) of the insulating sheet 111 and the first partial wires V1b, V1d, V1f, V1h, V1j, V1a formed on the first surface 1m (front surface) thereof.

This then forms a continuous wire Vc that conducts from the external terminal Vp→the first continuous portion Vs1→the inversion portion Vt→the second continuous portion Vs2→the common connection portion Cc.

Furthermore, the first continuous portion Vs1 and the second continuous portion Vs2 cross in a chain shape without mutual conduction in a projected plan view seen from the normal direction of the main surface of the insulating sheet 111. The annular portions continuously arrayed in a chain shape formed by the crossings each form a single coil.

Similarly, the continuous wire Wc to be energized with the W phase current includes a first continuous portion Ws1 and a second continuous portion Ws2 extending in the X direction of the insulating sheet 111. The first continuous portion Ws1 is configured by alternately cascading, through vias, corresponding ends of the second partial wires W2a, W2c, W2e, W2g, W2i, W2k formed on the second surface 2m (back surface) of the insulating sheet 111 and the first partial wires W1a, W1c, W1e, W1g, W1i, W1k formed on the first surface 1m (front surface) thereof.

The second continuous portion Ws2 is configured by alternately cascading, through vias, the corresponding ends of the second partial wires W2b, W2d, W2f, W2h, W2j, W2a formed on the second surface 2m (back surface) of the insulating sheet 111 and the first partial wires W1b, W1d, W1f, W1h, W1j, W1a formed on the first surface 1m (front surface) thereof.

This then forms a continuous wire Wc that conducts from the external terminal Wp→the first continuous portion Ws1→the inversion portion Wt→the second continuous portion Ws2→the common connection portion Cc.

Furthermore, the first continuous portion Ws1 and the second continuous portion Ws2 cross in a chain shape in a projected plan view seen from the normal direction of the main surface of the insulating sheet 111. The annular portions continuously arrayed in a chain shape formed by the crossings each form a single coil.

Hereinafter, the first partial wires V1a, V1b, V1c, V1d, V1e, V1f, V1g, V1h, V1i, V1j, V1k, V1a are also collectively referred to as the first partial wires V1. Furthermore, the second partial wires V2a, V2b, V2c, V2d, V2e, V2f, V2g, V2h, V2i, V2j, V2k, V2a are also collectively referred to as the second partial wires V2.

Similarly, the first partial wires W1a, W1b, W1c, W1d, W1e, W1f, W1g, W1h, W1i, W1j, W1k, W1a are also collectively referred to as the first partial wires W1. Furthermore, the second partial wires W2a, W2b, W2c, W2d, W2e, W2f, W2g, W2h, W2i, W2j, W2k, W2a are also collectively referred to as the second partial wires W2.

### [2. Arrangement Aspect of Reinforcing Wires]

A configuration is described in which reinforcing wires are formed on the flexible circuit board 110 to increase the strength of the flexible circuit board 110 for preventing decrease in strength of the flexible circuit board 110 and reducing the thickness of the flexible circuit board 110, thereby eliminating need to attach a reinforcing sheet or fill resin, with reference to FIGS. 15 to 17.

### Example 1

Example 1 is described with reference to FIG. 15. FIG. 15 shows a flexible circuit board 110a in which, for the flexible circuit board 110 shown in FIG. 13, first reinforcing wires Sa are formed on the first surface 1m (front surface) and second reinforcing wires Sb are formed on the second surface 2m (back surface). In FIG. 15, the vias where the first and second partial wires U1 and U2 of the U phase are connected are marked with the reference character U, the vias where the first and second partial wires V1 and V2 of the V phase are connected are marked with the reference character V, and the vias where the first and second partial wires W1 and W3 of the W phase are connected are marked with the reference character W.

On the first surface 1m (front surface) of the insulating sheet 111, the first partial wires U1 of the U phase, the first partial wires V1 of the V phase, and the first partial wires W1 of the W phase extend in the Y direction and are formed in parallel in order in the X direction. The first partial wires U1, V1, W1 correspond to first wires of the present disclosure. Then, on each of the long side 112a side and the long side 112b side of the insulating sheet 111, in the space H between the ends of the first partial wires U1 of the U phase, the first partial wires V1 of the V phase, and the first partial wires W1 of the W phase, and the end of the insulating sheet 111, L-shaped first reinforcing wires Sa are formed, each of which is conductive to one of adjacent first partial wires and extends in the X direction toward the other of the adjacent first partial wires. For example, a first reinforcing wire Sa is formed at each end of the first partial wire U1a, and extends in the X direction toward the adjacent first partial wire Vla.

Similarly, on the second surface 2m (back surface) of the insulating sheet 111, the U phase second partial wires U2, the V phase second partial wires V2, and the W phase second partial wires W2 extend in the Y direction and are formed in parallel in order in the X direction. The second partial wires U2, V2, W2 correspond to second wires of the present disclosure. Then, on each of the long sides 112a and 112b of the insulating sheet 111, in the space H between the ends of the second partial wires U2 of the U phase, the second partial wires V2 of the V phase, and the second partial wires W2 of the W phase, and the end of the insulating sheet 111, L-shaped second reinforcing wires Sb are formed, each of which is conductive to one of adjacent second partial wires and extends in the X direction. For example, a second reinforcing wires Sb are formed at each end of the second partial wire V2c, and extends in the X direction toward the adjacent second partial wire W2c.

J1 in FIG. 15 is a cross-sectional view taken along A1-A1 arrows of the flexible circuit board 110a, with the insulating sheet 111 made transparent when viewed from the long side 112a. K1 is a cross-sectional view taken along B1-B1 arrows of the flexible circuit board 110a, with the insulating sheet 111 made transparent when viewed from the long side 112b. As shown in K1 and J1, the first reinforcing wires Sa formed on the first surface 1 and the second reinforcing wires Sb formed on the second surface 2 are formed to have positions in the X direction partially overlapping each other.

As a result, wires are formed over the entire range in the X direction in which the coil pattern is formed on each side of the long side 112a and the long side 112b of the flexible circuit board 110a, making it possible to increase the strength of the flexible circuit board 110a. This eliminates need to attach a sheet or fill resin to reinforce the flexible circuit board 110a, making it possible to reduce the thickness of the flexible circuit board 110a. Furthermore, employing a stator configured with a flexible circuit board 110a makes it possible to reduce the size and weight of a rotating electric machine such as a motor.

### Example 2

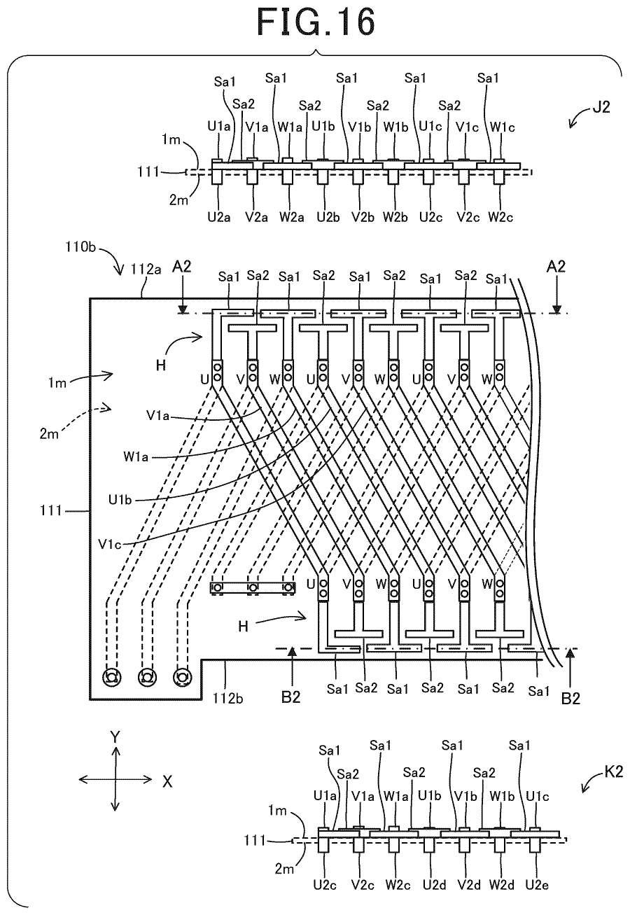

Example 2 of a formation pattern of reinforcing wires is described with reference to FIG. 16. FIG. 16 shows a flexible circuit board 110b in which the first first reinforcing wires Sa1 and the second first reinforcing wires Sa2 are formed on the first surface 1m of the flexible circuit board 110 shown in FIG. 13. In FIG. 16, the vias where the first and second partial wires U1 and U2 of the U phase are connected are marked with the reference character U, the vias where the first and second partial wires V1 and V2 of the V phase are connected are marked with the reference character V, and the vias where the first and second partial wires W1 and W3 of the W phase are connected are marked with the reference character W.

On the first surface 1m (front surface) of the insulating sheet 111, the first partial wires U1 of the U phase, the first partial wires V1 of the V phase, and the first partial wires W1 of the W phase extend in the Y direction and are formed in parallel in order in the X direction. The first partial wires U1, V1, W1 correspond to first wires of the present disclosure. Then, on each of the long side 112a side and the long side 112b side of the insulating sheet 111, in the space H between the ends of the first partial wires U1 of the U phase, the first partial wires V1 of the V phase, and the first partial wires W1 of the W phase, and the end of the insulating sheet 111, first first reinforcing wires Sa1 and second first reinforcing wires Sa2 are formed, each of which is conductive to one of adjacent first partial wires and extends in the X direction toward the other of the adjacent first partial wires.

For example, for a first partial wire W1a, a T-shaped first first reinforcing wire Sa1 is formed at each end on the long side 112a side and the long side 112b side. The first first reinforcing wire Sa1 is conductive to the first partial wire W1a and extends in the X-direction toward the first partial wire V1a and the first partial wire U1b each adjacent to the first partial wire W1a. For a first partial wire U1b, a T-shaped second first reinforcing wire Sa2 is formed at each end on the long side 112a side and the long side 112b side. The second first reinforcing wire Sa2 is conductive to the first partial wire U1b and extends in the X-direction toward the first partial wire W1a and the first partial wire V1b each adjacent to the first partial wire U1b. The first first reinforcing wires Sa1 and the second first reinforcing wires Sa2 are arranged at a distance in the Y direction.

J2 in FIG. 16 is a cross-sectional view taken along A2-A2 arrows of the flexible circuit board 110b, with the insulating sheet 111 made transparent when viewed from the long side 112a. K2 is a cross-sectional view taken along B2-B2 arrows of the flexible circuit board 110b, with the insulating sheet 111 made transparent when viewed from the long side 112b. As shown in J2 and K2, the first first reinforcing wires Sa1 and the second first reinforcing wires Sa2 formed on the first surface 1m are formed to have positions in the X direction partially overlapping each other.

As a result, wires are formed over the entire range in the X direction in which the coil pattern is formed on each side of the long side 112a and the long side 112b of the flexible circuit board 110b, making it possible to increase the strength of the flexible circuit board 110b. This eliminates need to attach a sheet or fill resin to reinforce the flexible circuit board 110b, making it possible to reduce the thickness of the flexible circuit board 110b. Furthermore, employing a stator configured with a flexible circuit board 110b makes it possible to reduce the size and weight of a rotating electric machine such as a motor.

### Example 3

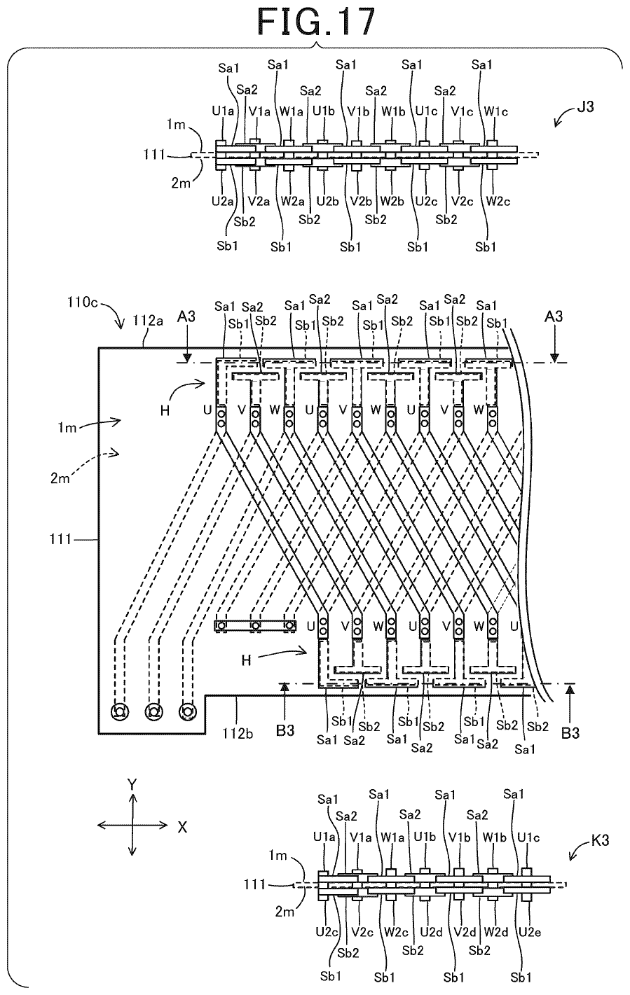

Example 3 is described with reference to FIG. 17. FIG. 17 shows a flexible circuit board 110c in which, for the flexible circuit board 110 shown in FIG. 13, first first reinforcing wires Sa1 and second first reinforcing wires Sa2 are formed on the first surface 1m (front surface) and first second reinforcing wires Sb1 and second second reinforcing wires Sb2 are formed on the second surface 2m (back surface).

On the first surface 1m (front surface) of the insulating sheet 111, the first first reinforcing wires Sa1 and the second first reinforcing wires Sa2 are formed in the same arrangement pattern as in the second example shown in FIG. 16. Also, on the second surface 2m (back surface) of the insulating sheet 111, the first second reinforcing wires Sb1 and the second second reinforcing wires Sb2 are formed in the same arrangement pattern as in the second example shown in FIG. 16.

In other words, on both the first surface 1m (front surface) and the second surface 2m (back surface) of the flexible circuit board 110c, the first first reinforcing wire Sa1 and the second first reinforcing wire Sa2 are formed on the first surface 1m (front surface), and the first second reinforcing wire Sb1 and the second second reinforcing wire Sb2 are formed on the second surface 2m (back surface) in the same arrangement pattern as the first first reinforcing wire Sa1 and the second first reinforcing wire Sa2 shown in the second embodiment above.

J3 in FIG. 17 is a cross-sectional view taken along A3-A3 arrows of the flexible circuit board 110c, with the insulating sheet 111 made transparent when viewed from the long side 112a. K3 is a cross-sectional view taken along B3-B3 arrows of the flexible circuit board 110c, with the insulating sheet 111 made transparent when viewed from the long side 112b. As shown in J3 and K3, on the first surface 1m, the first first reinforcing wires Sa1 and the second first reinforcing wires Sa2 are formed to have positions in the X direction partially overlapping each other, and on the second surface 2m, the first second reinforcing wires Sb1 and the second second reinforcing wires Sb2 are formed to have positions in the X direction partially overlapping each other.

As a result, on each of the long side 112a side and the long side 112b side of the flexible circuit board 110c, wires are formed over the entire range in the X direction where the coil pattern of the flexible circuit board 110c is formed, on each of the first surface 1m (front surface) and the second surface 2m (back surface), making it possible to increase the strength of the flexible circuit board 110c. This eliminates need to attach a protective sheet or fill resin to reinforce the flexible circuit board 110c, making it possible to reduce the thickness of the flexible circuit board 110c. Furthermore, employing a stator configured with a flexible circuit board 110c makes it possible to reduce the size and weight of a rotating electric machine such as a motor.

### 7. Other embodiments

In the above embodiment, as shown in FIGS. 15 to 17, examples are shown in each of which reinforcing wires are formed on each of the long side 112a side and the long side 112b side of the flexible circuit boards 110a, 110b, 110c. However, reinforcing wires may be formed only on the long side 112a side or only on the long side 112b side.

In the above embodiment, the first reinforcing wires Sa and the second reinforcing wires Sb of the flexible circuit board 110a shown in FIG. 15 are formed in such a manner as to have positions in the X direction partially overlapping each other. As a result, wires are formed over the entire range in the X direction in the range where the coil pattern of the flexible circuit board 110a is formed. As another embodiment, if the first reinforcing wires Sa and the second reinforcing wires Sb are configured to have positions in the X-direction that do not overlap each other, it is also possible to form the first reinforcing wires Sa and the second reinforcing wires Sb extending in the X-direction, thereby obtaining the effect of increasing the strength of the flexible circuit board 110a.

Similarly, the first first reinforcing wires Sa1 and the second first reinforcing wires Sa2 in the flexible circuit board 110b shown in FIG. 16, and the first first reinforcing wires Sa1 and the second first reinforcing wires Sa2, and the first second reinforcing wires Sb1 and the second second reinforcing wires Sb2 in the flexible circuit board 110c shown in FIG. 17 may also be arranged to have positions in the X direction that do not overlap each other.

The shapes of the reinforcing wires shown in FIGS. 15 to 17 are examples, and if the reinforcing wires of the present disclosure are formed on the first surface 1m (front surface) of the flexible circuit board 110 so as to be conductive to one of adjacent first partial wires among the first partial wires U1, V1, W1 in parallel and extend in the X direction toward the other of the adjacent first partial wires, the reinforcing wires can increase the strength of the flexible circuit board 110. In addition, if the reinforcing wires on the second surface 2m (back surface) of the flexible circuit board 110 are formed so as to be conductive to one of adjacent second partial wires among second partial wires U2, V2, W2 in parallel and extend in the X direction toward the other of the adjacent second partial wires, the reinforcing wires can increase the strength of the flexible circuit board 110.

The flexible circuit board of the present disclosure can also be applied to applications other than the stator of a rotating electric machine. For example, the flexible circuit board of the present disclosure may be used for noise removal applications such as choke coils rather than electromagnetic coils.

### 8. Configuration supported by the above embodiment

The above embodiments are specific examples of the following configurations.

### (Configuration 1)

A flexible circuit board, including a first sub-circuit board and a second sub-circuit board each including a flexible, band-shaped insulating sheet, a predetermined number of coil wires for a plurality of phases, and a connection portion having the predetermined number of connection terminals individually connected to the predetermined number of the coil wires, the predetermined number of the coil wires being formed so as to extend in a longitudinal direction of the insulating sheet and being arranged in parallel at intervals, wherein the first sub-circuit board has the connection portion arranged at a first longitudinal end that is one longitudinal end of the insulating sheet, and has a connection setting set to a first connection setting, the connection setting being made between the predetermined number of the connection terminals and an external circuit to supply drive currents of the plurality of phases, the first connection setting being made in such a manner that a rotating magnetic field in a predetermined direction in a longitudinal direction of the insulating sheet is generated by the coil wires when drive currents of the plurality of phases are supplied from the external circuit to the predetermined number of the connection terminals, the second sub-circuit board has the connection portion arranged at a second longitudinal end that is another longitudinal end of the insulating sheet, and has a connection setting set to a second connection setting, the connection setting being made between the predetermined number of the connection terminals and the external circuit, the second connection setting being made in such a manner that a rotating magnetic field in the predetermined direction in a longitudinal direction of the insulating sheet is generated by the coil wires when drive currents of the plurality of phases are supplied from the external circuit to the predetermined number of the connection terminals, and the first sub-circuit board and the second sub-circuit board are arrayed in a longitudinal direction of the insulating sheet with the first longitudinal end of the first sub-circuit board and the second longitudinal end of the second sub-circuit board adjacent to each other, and are bent into a cylindrical shape, thereby forming a stator for a rotating electric machine.

The flexible circuit board of configuration 1 makes it possible to array the first sub-circuit board and the second sub-circuit board with the ends at which the connection portions are arranged being adjacent to each other, thereby bringing together the connection points with the external circuit and configuring a flexible circuit board that is longer than the first sub-circuit board and the second sub-circuit board. This makes it possible to provide a flexible circuit board that can eliminate the need for a long-length printing process and can form a stator that is compatible with a large motor and is easily connected to an external circuit.

### (Configuration 2)

The flexible circuit board according to configuration 1, wherein the second sub-circuit board is configured in such a manner that a first surface and a second surface of the first sub-circuit board are inverted around an axis in a short-side direction of the insulating sheet.

The flexible circuit board of configuration 2 allows the first sub-circuit board and the second sub-circuit board to have the same specifications. This makes it easier to manage the first sub-circuit board and the second sub-circuit board when manufacturing the flexible circuit board.

### (Configuration 3)

The flexible circuit board according to configuration 1 or 2, the flexible circuit board being configured in such a manner that the first sub-circuit board and the second sub-circuit board are arrayed in a longitudinal direction of the insulating sheet with the first longitudinal end of the first sub-circuit board and the second longitudinal end of the second sub-circuit board adjacent to each other to create a paired circuit board, and a plurality of sets of the paired circuit boards are arrayed in a longitudinal direction of the insulating sheet.

The flexible circuit board of configuration 3 makes it possible to combine the first sub-circuit board and the second sub-circuit board to create a paired circuit and array a plurality of the paired circuits, thereby easily making a long flexible circuit longer.

### (Configuration 4)

The flexible circuit board according to any one of configurations 1 to 3, wherein the first sub-circuit board and the second sub-circuit board each have a reinforcing wire formed in a space of the insulating sheet between ends of the coil wires in a short-side direction of the insulating sheet and the first longitudinal end or the second longitudinal end on at least one of first and second surfaces of the insulating sheet, the reinforcing wire being conductive to one of ends of the adjacent coil wires in a short-side direction of the insulating sheet, the reinforcing wire extending in a longitudinal direction of the insulating sheet toward another of ends of the adjacent coil wires.

The flexible circuit board of configuration 4 makes it possible to form reinforcing wires in the first sub-circuit board and the second sub-circuit board, thereby increasing the strength of the flexible circuit board. This makes it possible to eliminate the need to attach a reinforcing sheet or fill resin to the flexible circuit board to reduce the thickness of the flexible circuit board.

### (Configuration 5)

The flexible circuit board according to any one of configurations 1 to 4, wherein the first sub-circuit board and the second sub-circuit board each have a positioning protrusion formed at an end of the insulating sheet in a short-side direction.

The flexible circuit board of configuration 5 makes it possible to provide the first sub-circuit board and the second sub-circuit board with positioning protrusions, thereby making it easier to assemble the flexible circuit to reduce the number of steps in assembling the stator configuration using the flexible circuit board.

### (Configuration 6)

A rotating electric machine, including: a first sub-circuit board and a second sub-circuit board each including a flexible, band-shaped insulating sheet, a predetermined number of coil wires for a plurality of phases, and a connection portion having the predetermined number of connection terminals individually connected to the predetermined number of the coil wires, the predetermined number of the coil wires being formed so as to extend in a longitudinal direction of the insulating sheet and being arranged in parallel at intervals, wherein the first sub-circuit board has the connection portion arranged at a first longitudinal end that is one longitudinal end of the insulating sheet, and has a connection setting set to a first connection setting, the connection setting being made between the predetermined number of the connection terminals and an external circuit to supply drive currents of the plurality of phases, the first connection setting being made in such a manner that a rotating magnetic field in a predetermined direction in a longitudinal direction of the insulating sheet is generated by the coil wires when drive currents of the plurality of phases are supplied from the external circuit to the predetermined number of the connection terminals, and the second sub-circuit board has the connection portion arranged at a second longitudinal end that is another longitudinal end of the insulating sheet, and has a connection setting set to a second connection setting, the connection setting being made between the predetermined number of the connection terminals and the external circuit, the second connection setting being made in such a manner that a rotating magnetic field in the predetermined direction in a longitudinal direction of the insulating sheet is generated by the coil wires when drive currents of the plurality of phases are supplied from the external circuit to the predetermined number of the connection terminals; and a stator configured in such a manner that the first sub-circuit board and the second sub-circuit board are arrayed in a longitudinal direction of the insulating sheet with the first longitudinal end of the first sub-circuit board and the second longitudinal end of the second sub-circuit board adjacent to each other, and are bent into a cylindrical shape.

The rotating electric machine of configuration 6 makes it possible to configure a stator with a flexible circuit board similar to the flexible circuit board of configuration 1, thereby eliminating need for a long-length printing process to form a large motor that is easily wired for an external circuit.

### (Configuration 7)

A flexible circuit board including: an insulating sheet having flexibility and a band shape; a plurality of first wires that are formed in parallel in a longitudinal direction of the insulating sheet and extend in a short-side direction of the insulating sheet, on a first surface of the insulating sheet; and a first reinforcing wire that is formed in a space on the first surface so as to be conductive to one of the first wires of the adjacent first wires and extend in a longitudinal direction of the insulating sheet toward another of the first wires of the adjacent first wires, the space being located between ends of a plurality of the first wires on at least one side in a short-side direction of the insulating sheet and a corresponding end of the insulating sheet in a short-side direction.

The flexible circuit board of configuration 7 makes it possible to form a first reinforcing wire extending in the longitudinal direction of the insulating sheet in the space on the first surface where the first wire is not formed between one ends of adjacent first wires and the end of the insulating sheet in the short-side direction, thereby reducing the portion where no wire is formed in the longitudinal direction of the insulating sheet. This makes it possible to prevent decrease in the strength of the insulating sheet while eliminating need to attach a reinforcing sheet or apply resin, to reduce the thickness of the flexible circuit board.

### (Configuration 8)

The flexible circuit board according to configuration 7, wherein the first reinforcing wire includes a first first reinforcing wire that is conductive to one of the first wires of the adjacent first wires, and a second first reinforcing wire that is conductive to another of the first wires of the adjacent first wires, and the first first reinforcing wire and the second first reinforcing wire are formed with an interval in a short-side direction of the insulating sheet and are formed in such a manner as to have positions in a longitudinal direction of the insulating sheet partially overlapping each other.

The flexible circuit board of configuration 8 makes it possible to form the first first reinforcing wire and the second first reinforcing wire in such a manner as to have positions in the longitudinal direction of the insulating sheet partially overlapping each other, thereby reducing the portion where no wire is formed in the longitudinal direction of the insulating sheet on the first surface to increase the strength of the flexible circuit board.

### (Configuration 9)

The flexible circuit board according to configuration 7 or 8, further including: a plurality of second wires that are formed in parallel in a longitudinal direction of the insulating sheet and extend in a short-side direction of the insulating sheet, on a second surface of the insulating sheet; and a second reinforcing wire that is formed in a space on the second surface so as to be conductive to one of the second wires of the adjacent second wires and extend in a longitudinal direction of the insulating sheet toward another of the second wires of the adjacent second wires, the space being located between ends of a plurality of the second wires on at least one side in a short-side direction of the insulating sheet and a corresponding end of the insulating sheet in a short-side direction.

The flexible circuit board of configuration 9 makes it possible to form the second reinforcing wire on the second surface of the insulating sheet in the same manner as on the first surface, thereby increasing the strength of the flexible circuit board.

### (Configuration 10)

The flexible circuit board according to any one of configurations 7 to 9, wherein the first reinforcing wire and the second reinforcing wire adjacent to each other in a longitudinal direction of the insulating sheet via the insulating sheet are formed in such a manner as to have positions in a longitudinal direction of the insulating sheet partially overlapping each other.

The flexible circuit board of configuration 10 makes it possible to form the first reinforcing wire and the second reinforcing wire adjacent to each other via the insulating sheet in such a manner as to have positions in the longitudinal direction of the insulating sheet partially overlapping each other, thereby reducing the portion where no wire is formed in the longitudinal direction of the insulating sheet to increase the strength of the flexible circuit board.

### (Configuration 11)

The flexible circuit board according to any one of configurations 7 to 10, wherein the second reinforcing wire includes a first second reinforcing wire that is conductive to one of the second wires of the adjacent second wires, and a second second reinforcing wire that is connected to another of the second wires of the adjacent second wires, and the first second reinforcing wire and the second second reinforcing wire are formed with an interval in a short-side direction of the insulating sheet and are formed in such a manner as to have positions in a longitudinal direction of the insulating sheet partially overlapping each other.

The flexible circuit board of configuration 11 makes it possible to form the first second reinforcing wire and the second second reinforcing wire in such a manner as to have positions in the longitudinal direction of the insulating sheet partially overlapping each other, thereby reducing the portion where no wire is formed in the longitudinal direction of the insulating sheet on the second surface to increase the strength of the flexible circuit board.

### (Configuration 12)

The flexible circuit board according to any one of configurations 7 to 11, wherein a plurality of the first wires and the second wires are arranged in parallel in such a manner as to have end positions overlapping each other in a normal direction of the insulating sheet at the same intervals, and opposing ends of a plurality of the first wires and the second wires via the insulating sheet are connected by vias to form a continuous wire that forms a coil.

The flexible circuit board of configuration 12 makes it possible to reduce the thickness of the flexible circuit board forming the coil while preventing decrease in strength.

### (Configuration 13)

A rotating electric machine including a stator configured with a flexible circuit board, wherein the flexible circuit board includes: an insulating sheet having flexibility and a band shape; a plurality of first wires that are formed in parallel in a longitudinal direction of the insulating sheet and extend in a short-side direction of the insulating sheet, on a first surface of the insulating sheet; a first reinforcing wire that is formed in a space on the first surface so as to be conductive to one of the first wires of the adjacent first wires and extend in a longitudinal direction of the insulating sheet toward another of the first wires of the adjacent first wires, the space being located between ends of a plurality of the first wires on at least one side in a short-side direction of the insulating sheet and a corresponding end of the insulating sheet in a short-side direction; and a plurality of second wires that are formed in parallel in a longitudinal direction of the insulating sheet and extend in a short-side direction of the insulating sheet, on a second surface of the insulating sheet, and the flexible circuit board has a plurality of the first wires and the second wires that are arranged in parallel in such a manner as to have end positions overlapping each other in a normal direction of the insulating sheet at the same intervals, and opposing ends of a plurality of the first wires and the second wires via the insulating sheet are connected by vias to form a continuous wire that forms a coil.

The rotating electric machine of configuration 13 makes it possible to cause the first reinforcing wire formed on the first surface to prevent decrease in strength to eliminate the need to attach a reinforcing sheet or fill resin, thereby reducing the thickness of the flexible circuit board. Using the stator configured with this flexible circuit board makes it possible to reduce the size and weight of a rotating electric machine.

### (Configuration 14)

The rotating electric machine according to configuration 13, wherein the flexible circuit board includes a second reinforcing wire that is formed in a space on the second surface so as to be conductive to one of the second wires of the adjacent second wires and extend in a longitudinal direction of the insulating sheet toward another of the second wires of the adjacent second wires, the space being located between ends of a plurality of the second wires on at least one side in a short-side direction of the insulating sheet and a corresponding end of the insulating sheet in a short-side direction.

The rotating electric machine of configuration 14 makes it possible to form the second reinforcing wire on the second surface of the insulating sheet of the flexible circuit board forming the stator, thereby increasing the strength of the stator forming the rotating electric machine.

### REFERENCE SIGNS LIST

1, 110 (110a, 110b, 110c) . . . flexible circuit board, 11a, 1m . . . first surface (front surface), 12a, 2m . . . second surface (back surface), 2a . . . first sub-circuit board, 2b . . . first sub-circuit board, 10a, 10b, 111 . . . insulating sheet, 20a, 20b . . . connection portion, 21a to 23a, 21b to 23b . . . connection terminal, 31a to 33a, 31b to 33b . . . coil wire, 40 . . . positioning protrusion, 41 . . . thermal conductive pattern, 50, 150 . . . motor, 51, 151 . . . case, 60, 160 . . . rotor, 70, 170 . . . stator, 71a, 71b . . . external terminal, 90 . . . external circuit, Sa . . . first reinforcing wire, Sa1 . . . first first reinforcing wire, Sa2 . . . second first reinforcing wire, Sb . . . second reinforcing wire, Sb1 . . . first second reinforcing wire, Sb2 . . . second second reinforcing wire, U1 (U1a to U1d) . . . first partial wires of U phase, V1 (V1a to V1d) . . . first partial wires of V phase, W1 (W1a to W1d) . . . first partial wires of W phase, U2 (U2a to U2d) . . . second partial wires of U phase, V2 (V2a to V2d) . . . second partial wires of V phase, W2 (W2a to W2d) . . . second partial wires of W phase, U3 (U3a to U3d) . . . third partial wires of U phase, V3 (U3a to V3d) . . . third partial wires of V phase, W3 (W3a to W3d) . . . third partial wires of W phase, U4 (U4a to U4d) . . . fourth partial wires of U phase, Us1 . . . first continuous portion of U phase, Us2 . . . second continuous portion of U phase, Uc . . . continuous wire of U phase, Vs1 . . . first continuous portion of V phase, Vs2 . . . second continuous portion of V phase, Vc . . . continuous wire of V phase, Ws1 . . . first continuous portion of W phase, Ws2 . . . second continuous portion of W phase, Wc . . . continuous wire of W phase.

1. A flexible circuit board, comprising a first sub-circuit board and a second sub-circuit board each including a flexible, band-shaped insulating sheet, a predetermined number of coil wires for a plurality of phases, and a connection portion having the predetermined number of connection terminals individually connected to the predetermined number of the coil wires, the predetermined number of the coil wires being formed so as to extend in a longitudinal direction of the insulating sheet and being arranged in parallel at intervals, wherein
the first sub-circuit board has the connection portion arranged at a first longitudinal end that is one longitudinal end of the insulating sheet, and has a connection setting set to a first connection setting, the connection setting being made between the predetermined number of the connection terminals and an external circuit to supply drive currents of the plurality of phases, the first connection setting being made in such a manner that a rotating magnetic field in a predetermined direction in a longitudinal direction of the insulating sheet is generated by the coil wires when drive currents of the plurality of phases are supplied from the external circuit to the predetermined number of the connection terminals,
the second sub-circuit board has the connection portion arranged at a second longitudinal end that is another longitudinal end of the insulating sheet, and has a connection setting set to a second connection setting, the connection setting being made between the predetermined number of the connection terminals and the external circuit, the second connection setting being made in such a manner that a rotating magnetic field in the predetermined direction in a longitudinal direction of the insulating sheet is generated by the coil wires when drive currents of the plurality of phases are supplied from the external circuit to the predetermined number of the connection terminals, and
the first sub-circuit board and the second sub-circuit board are arrayed in a longitudinal direction of the insulating sheet with the first longitudinal end of the first sub-circuit board and the second longitudinal end of the second sub-circuit board adjacent to each other, and are bent into a cylindrical shape, thereby forming a stator for a rotating electric machine.

2. The flexible circuit board according to claim 1, wherein the second sub-circuit board is configured in such a manner that a first surface and a second surface of the first sub-circuit board are inverted around an axis in a short-side direction of the insulating sheet.

3. The flexible circuit board according to claim 1, the flexible circuit board being configured in such a manner that the first sub-circuit board and the second sub-circuit board are arrayed in a longitudinal direction of the insulating sheet with the first longitudinal end of the first sub-circuit board and the second longitudinal end of the second sub-circuit board adjacent to each other to create a paired circuit board, and a plurality of sets of the paired circuit boards are arrayed in a longitudinal direction of the insulating sheet.

4. The flexible circuit board according to claim 1, wherein the first sub-circuit board and the second sub-circuit board each have a reinforcing wire formed in a space of the insulating sheet between ends of the coil wires in a short-side direction of the insulating sheet and the first longitudinal end or the second longitudinal end on at least one of first and second surfaces of the insulating sheet, the reinforcing wire being conductive to one of ends of the adjacent coil wires in a short-side direction of the insulating sheet, the reinforcing wire extending in a longitudinal direction of the insulating sheet toward another of ends of the adjacent coil wires.

5. The flexible circuit board according to claim 1, wherein the first sub-circuit board and the second sub-circuit board each have a positioning protrusion formed at an end of the insulating sheet in a short-side direction.

6. A rotating electric machine, comprising:
a first sub-circuit board and a second sub-circuit board each including a flexible, band-shaped insulating sheet, a predetermined number of coil wires for a plurality of phases, and a connection portion having the predetermined number of connection terminals individually connected to the predetermined number of the coil wires, the predetermined number of the coil wires being formed so as to extend in a longitudinal direction of the insulating sheet and being arranged in parallel at intervals, wherein
the first sub-circuit board has the connection portion arranged at a first longitudinal end that is one longitudinal end of the insulating sheet, and has a connection setting set to a first connection setting, the connection setting being made between the predetermined number of the connection terminals and an external circuit to supply drive currents of the plurality of phases, the first connection setting being made in such a manner that a rotating magnetic field in a predetermined direction in a longitudinal direction of the insulating sheet is generated by the coil wires when drive currents of the plurality of phases are supplied from the external circuit to the predetermined number of the connection terminals, and
the second sub-circuit board has the connection portion arranged at a second longitudinal end that is another longitudinal end of the insulating sheet, and has a connection setting set to a second connection setting, the connection setting being made between the predetermined number of the connection terminals and the external circuit, the second connection setting being made in such a manner that a rotating magnetic field in the predetermined direction in a longitudinal direction of the insulating sheet is generated by the coil wires when drive currents of the plurality of phases are supplied from the external circuit to the predetermined number of the connection terminals; and
a stator configured in such a manner that the first sub-circuit board and the second sub-circuit board are arrayed in a longitudinal direction of the insulating sheet with the first longitudinal end of the first sub-circuit board and the second longitudinal end of the second sub-circuit board adjacent to each other, and are bent into a cylindrical shape.

7. A flexible circuit board comprising:
an insulating sheet having flexibility and a band shape;
a plurality of first wires that are formed in parallel in a longitudinal direction of the insulating sheet and extend in a short-side direction of the insulating sheet, on a first surface of the insulating sheet; and
a first reinforcing wire that is formed in a space on the first surface so as to be conductive to one of the first wires of the adjacent first wires and extend in a longitudinal direction of the insulating sheet toward another of the first wires of the adjacent first wires, the space being located between ends of a plurality of the first wires on at least one side in a short-side direction of the insulating sheet and a corresponding end of the insulating sheet in a short-side direction.

8. The flexible circuit board according to claim 7, wherein
the first reinforcing wire includes a first first reinforcing wire that is conductive to one of the first wires of the adjacent first wires, and a second first reinforcing wire that is conductive to another of the first wires of the adjacent first wires, and
the first first reinforcing wire and the second first reinforcing wire are formed with an interval in a short-side direction of the insulating sheet and are formed in such a manner as to have positions in a longitudinal direction of the insulating sheet partially overlapping each other.

9. The flexible circuit board according to claim 7, further comprising:
a plurality of second wires that are formed in parallel in a longitudinal direction of the insulating sheet and extend in a short-side direction of the insulating sheet, on a second surface of the insulating sheet; and
a second reinforcing wire that is formed in a space on the second surface so as to be conductive to one of the second wires of the adjacent second wires and extend in a longitudinal direction of the insulating sheet toward another of the second wires of the adjacent second wires, the space being located between ends of a plurality of the second wires on at least one side in a short-side direction of the insulating sheet and a corresponding end of the insulating sheet in a short-side direction.

10. The flexible circuit board according to claim 7, wherein the first reinforcing wire and the second reinforcing wire adjacent to each other in a longitudinal direction of the insulating sheet via the insulating sheet are formed in such a manner as to have positions in a longitudinal direction of the insulating sheet partially overlapping each other.

11. The flexible circuit board according to claim 7, wherein
the second reinforcing wire includes a first second reinforcing wire that is conductive to one of the second wires of the adjacent second wires, and a second second reinforcing wire that is connected to another of the second wires of the adjacent second wires, and
the first second reinforcing wire and the second second reinforcing wire are formed with an interval in a short-side direction of the insulating sheet and are formed in such a manner as to have positions in a longitudinal direction of the insulating sheet partially overlapping each other.

12. The flexible circuit board according to claim 7, wherein a plurality of the first wires and the second wires are arranged in parallel in such a manner as to have end positions overlapping each other in a normal direction of the insulating sheet at the same intervals, and opposing ends of a plurality of the first wires and the second wires via the insulating sheet are connected by vias to form a continuous wire that forms a coil.

13. A rotating electric machine comprising a stator configured with a flexible circuit board, wherein
the flexible circuit board includes:
an insulating sheet having flexibility and a band shape;
a plurality of first wires that are formed in parallel in a longitudinal direction of the insulating sheet and extend in a short-side direction of the insulating sheet, on a first surface of the insulating sheet;
a first reinforcing wire that is formed in a space on the first surface so as to be conductive to one of the first wires of the adjacent first wires and extend in a longitudinal direction of the insulating sheet toward another of the first wires of the adjacent first wires, the space being located between ends of a plurality of the first wires on at least one side in a short-side direction of the insulating sheet and a corresponding end of the insulating sheet in a short-side direction; and
a plurality of second wires that are formed in parallel in a longitudinal direction of the insulating sheet and extend in a short-side direction of the insulating sheet, on a second surface of the insulating sheet, and
the flexible circuit board has a plurality of the first wires and the second wires that are arranged in parallel in such a manner as to have end positions overlapping each other in a normal direction of the insulating sheet at the same intervals, and opposing ends of a plurality of the first wires and the second wires via the insulating sheet are connected by vias to form a continuous wire that forms a coil.

14. The rotating electric machine according to claim 13, wherein the flexible circuit board includes a second reinforcing wire that is formed in a space on the second surface so as to be conductive to one of the second wires of the adjacent second wires and extend in a longitudinal direction of the insulating sheet toward another of the second wires of the adjacent second wires, the space being located between ends of a plurality of the second wires on at least one side in a short-side direction of the insulating sheet and a corresponding end of the insulating sheet in a short-side direction.
